(19) United States
(12) Patent Application Publication
(10) Pub. No.: US 2017/0210903 A1
(43) Pub. Date: Jul. 27, 2017

(54) FLUORESCENT DYE COMPOUND HAVING BENZOTRIAZOLE STRUCTURE AND WAVELENGTH-CONVERTING ENCAPSULANT COMPOSITION USING SAME

(71) Applicant: NITTO DENKO CORPORATION, Osaka (JP)

(72) Inventors: Shoichi KAWAMITSU, Osaka (JP); Sadahiro NAKANISHI, Osaka (JP); Miyuki KUROGI, Osaka (JP); Hisanari ONOUCHI, Osaka (JP)

(21) Appl. No.: 15/327,773

(22) PCT Filed: Jul. 16, 2015
(86) PCT No.: PCT/JP2015/070403

§ 371 Date: Jan. 20, 2017

(30) Foreign Application Priority Data
Jul. 24, 2014 (JP) 2014-150614

(51) Int. Cl. C09B 57/00; H01L 31/048; H01L 31/028; H01L 31/055; C09B 69/10; C09K 11/06

(52) U.S. Cl. CPC C09B 57/00; C09B 69/10; C09K 11/06; H01L 31/028; H01L 31/055; H01L 31/0481; C09K 2211/1059

(57) ABSTRACT

The present invention relates to fluorescent, benzotriazole-containing dye compounds, which possess a high workability, desirable optical properties, and a good light stability, while suppressing the formation of a precipitate. The invention further relates to a wavelength-converting encapsulant layer, which is formed using the wavelength-converting encapsulant composition comprising said fluorescent, benzotriazole dye compounds. The fluorescent, benzotriazole-containing dye compounds are represented by general formula (I).

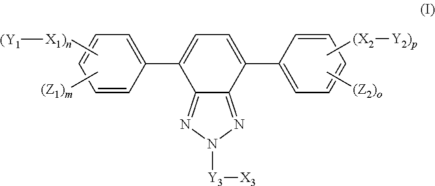

wherein the variables are defined in the specification.

### TECHNICAL FIELD

The present invention relates to a fluorescent dye compound which has a benzotriazole structure to have a favorable absorption wavelength and an excellent light stability when used in, e.g., a solar cell encapsulant composition or a fluorescent film forming material; and a wavelength-converting encapsulant composition, a wavelength-converting encapsulant layer (such as a wavelength-converting film or a wavelength-converting sheet), and a solar cell module each using the compound. The wavelength-converting encapsulant layer has a potential of attaining a remarkable enhancement of the sunlight collecting efficiency of a photoelectromotive device or a solar cell device.

### BACKGROUND ART

The use of solar energy supplies a promising energy alternate for conventional fossil fuels. In recent years, therefore, a great attention has been paid to the development of devices capable of converting solar energy to electricity, for example, the development of a photoelectromotive device (also known as a solar cell) and others. Mature photoelectromotive devices of some different types have been developed. Examples thereof include silicon devices, III-V and II-VI PN junction devices, copper-indium-gallium-selenium (CIGS) thin film devices, organic sensitizer devices, organic thin film devices, and cadmium-sulfide/cadmium-telluride (CdS/CdTe) thin film devices. Details of these devices can be found out in documents and others (see, for example, Non-Patent Document 1). However, about the photoelectric conversion efficiency of many of these devices, there has still been a room for improvement. For many researches, the development of a technique for improving this efficiency is a theme which is being tackled.

In order to improve the conversion efficiency, investigations have been made about solar cells having such a wavelength-converting function that wavelengths not contributing to photoelectric conversion (for example, ultraviolet wavelengths), out of wavelengths of rays radiated into the cells, are converted to wavelengths contributing to photoelectric conversion (see, for example, Patent Document 2). According to the investigations, a suggestion is made about a method of mixing a fluorophore powder with a resin material to form an emission panel.

Wavelength-converting inorganic media to be used in photoelectromotive devices and solar cells have been so far disclosed. However, reports have hardly been made about researches on the use of a photoluminescent organic medium in a photoelectromotive device for improving the efficiency of the device. In contrast to inorganic media, organic material is typically more inexpensive, and is easier to use. From this matter, attention is paid to the use of organic media in the point that the selection of organic material becomes a better economical selection.

It has also made evident that the use of the above-mentioned fluorophore powder causes inconveniences, for example, the precipitation of the added fluorophore with time. In a case where the powder is used, particularly, for solar cells, improvements of such a stability over time, and storage stability for a long term are particularly important themes since it is conceived that the solar cells are used outdoors over a long term of 20 years or longer.

### PRIOR ART DOCUMENTS

### Patent Documents

PATENT DOCUMENT 1: US-A-2009/0151785

PATENT DOCUMENT 2: JP-A-H07-142752

### SUMMARY OF THE INVENTION

### Problems to be Solved by the Invention

In light of such a situation, an object of the present invention is to provide a fluorescent dye compound which is a novel benzotriazole derivative as a novel compound that has a high workability, desired optical properties, and a good light stability and that is restrained from being precipitated; and a wavelength-converting encapsulant composition using this compound.

Another object of the present invention is to provide a wavelength-converting encapsulant layer which is formed using the wavelength-converting encapsulant composition, thereby having desired optical properties and a good light stability and being restrained from being precipitated; and a photoelectromotive module having this layer.

### Means for Solving the Problems

In order to solve the above-mentioned problems, the inventors have made eager investigations to succeed in creating a novel organic compound having a benzotriazole structure described below, and find out that the above-mentioned objects through the compound can be attained. Thus, the present invention has been accomplished.

The light wavelength-converting organic compound of the present invention is fixable to a polymer matrix through a chemical bond.

Since the light wavelength-converting organic compound of the present invention is fixable to a polymer matrix through a chemical bond, this compound can attain light wavelength conversion while keeping properties of the organic fluorescent dye even when the polymer matrix is used to make the compound, or dye into a encapsulant composition or a sheet.

It is preferred that the light wavelength-converting organic compound of the present invention is fixable thereto by a crosslinking reaction, cyclization reaction, substitution reaction, or polymerization reaction.

It is preferred that the light wavelength-converting organic compound of the present invention is a benzotriazole derivative. As the light wavelength-converting organic compound, for example, a fluorescent dye compound (general formula (I) illustrated below) in the present invention is preferably used.

It is preferred in the light wavelength-converting organic compound that the polymer matrix comprises, as a main component thereof, an ethylene-vinyl acetate copolymer. The polymer matrix is preferably an optically transparent resin in order to be optically used in, e.g., solar cells. Furthermore, the polymer matrix comprising the above-mentioned main component makes it easy to fix the light wavelength-converting organic compound on the basis of, particularly, the formation of a covalent bond.

The fluorescent dye compound of the present invention is represented by the following general formula (I):

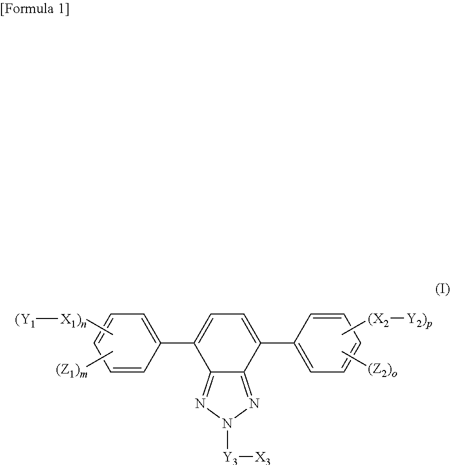

wherein X₁(s) and X₂(s) each independently represent —O—, —(C═O) O—, —O(C═O)—, —CH₂O—, —CH₂O(CO)—, —NH(CO)—, —NR—CH₂—, or a single bond wherein R represents an alkyl group having 1 to 8 carbon atoms;

X₃ represents a group containing a carbon-carbon double bond, or hydrogen;

Y₁(s) and Y₂(s) each independently represent an optionally-substituted alkyl group having 1 to 18 carbon atoms, or an optionally-substituted alkyl group having a carbon-carbon double bond and having 2 to 18 carbon atoms (provided that one or two out of any nonadjacent two of the carbon atoms in the alkyl group may (each) be substituted with an oxygen atom);

Y₃ represents an optionally-substituted alkyl group having 1 to 18 carbon atoms, an optionally-substituted aryl group having 5 to 18 carbon atoms, or an optionally-substituted alkyl group having a carbon-carbon double bond and having 2 to 18 carbon atoms (provided that one or two out of any nonadjacent two of the carbon atoms in the alkyl group may (each) be substituted with an oxygen atom);

Z₁(s) and Z₂(s) each independently represent an optionally-substituted alkyl group having 1 to 18 carbon atoms (provided that one or two out of any nonadjacent two of the carbon atoms in the alkyl group may (each) be substituted with an oxygen atom), an optionally-substituted alkoxy group having 1 to 18 carbon atoms (provided that one or two out of any nonadjacent two of the carbon atoms in the alkoxy group may (each) be substituted with an oxygen atom), a fluoro group, a cyano group, —COOR¹ group, —NHCOR² group, or a hydroxyl group wherein R¹ and R² each represent an alkyl group having 1 to 18 carbon atoms or a phenyl group; and

m, n, o and p each independently represent an integer of 0 to 4 (provided that m+n is 4 or less, and o+p is 4 or less), and when m, n, o or p is 2 or more, the substituents concerned may be the same as or different from each other.

The fluorescent dye compound of the present invention has the structure represented by the general formula (I). Thus, the compound can be an excellent compound having a high workability, desired optical properties (such as a high quantum yield) and a good light stability (chemical and physical stability). The organic dye compound which is, particularly, dispersed in a matrix resin can easily give a stable and uniform encapsulant composition (and layer) without being precipitated even in a long-term storage test. About the expression of the effects and advantages, it is presumed at present that a mechanism described below contributes mainly to the expression. However, it is not specified that the expression is indispensably via the mechanism. It is presumed that the fluorescent dye compound is chemically linked to a matrix polymer to be restrained from being shifted inside the matrix resin. As a result, this compound can be restrained from undergoing, for example, crystallization followed by being precipitated or being discharged to the outside of the layer.

When a fluorescence-emitting chemical structure moiety of a molecule is linked to a different aromatic moiety of the or another molecule, the compound may be unfavorably changed in absorbing/light-emitting properties, and further the aromatic moiety formed by the linking may also be lowered in light stability. Thus, it is feared that the compound is deteriorated, particularly, in absorbing/light-emitting properties and others when the compound is used outdoors for, e.g., solar cells. It is therefore preferred in the fluorescent dye compound of the present invention that its chromophore, which has the specified benzotriazole structure, is linked to a matrix polymer through a non-conjugated bond. In this case, the absorbing/light-emitting properties s of the chromophore are substantially kept to make it easy to predict or adjust the absorbing/light-emitting properties on the basis of the introduction of the compound into the polymer matrix. Moreover, about the fluorescent dye compound of the present invention, for example, a bonding moiety of the benzotriazole structure is, for example, bonded to not only a monomer moiety of a matrix-polymer that expresses a main function of the matrix polymer but also another monomer moiety thereof, thereby making it possible to control secondary properties of the resultant, such as the glass transition temperature (Tg) and solubility thereof. This matter is advantageous for making it easier to disperse or dissolve the fluorescent dye compound evenly in the system concerned in the step of working the compound or the composition, for example, the step of heating and kneading the same. In general, a dye compound having a heterocyclic structure may be poor in solubility because of the planarity or crystallinity thereof; however, the fluorescent dye compound of the present invention has an effect that a high crystallinity of this compound, which is based on the benzotriazole structure, is lowered by such an action that this compound is made amorphous by the above-mentioned X-Y groups. It is presumed that this effect also affects. Additionally, the use of the fluorescent dye compound makes it possible to control the absorption wavelength of the fluorescent dye compound precisely. Thus, the compound is particularly suitable for solar cells.

In the fluorescent dye compound of the present invention, it is preferred that the symbol X₃ is preferably —CR′═CH₂, —(C═O)O—CR′═CH₂, —O(C═O)—CR′═CH₂, —CH₂O(CO)—CR′═CH₂, —NH(CO)—CR′═CH₂, or —NR—CH₂—CR′═CH₂ wherein R and R's each independently represent an alkyl group having 1 to 8 carbon atoms. When the compound has this structure, it becomes easy to form a chemical bond of the compound to the matrix resin through the X₃ group, in particular, a bond thereof that is based on, e.g., radical linkage or radical polymerization reaction.

It is also preferred that the fluorescent dye compound of the present invention has a maximum absorption wavelength in a wavelength range from 300 to 410 nm. When the compound has the maximum absorption wavelength in this wavelength range, the compound makes it possible to convert more effectively incident rays having wavelengths which are not easily used (or not usable) for photoelectric conversion by a solar cell into a wavelength range which can be photoelectrically converted by the solar cell or the like. In the invention, the maximum absorption wavelength denotes a wavelength at which the absorbed-light quantity of the light absorbed by this compound is a maximum value, and is measurable as a wavelength at which the compound shows a maximum absorption peak in an ultraviolet absorption spectrum thereof.

It is also preferred that the fluorescent dye compound of the present invention has a maximum fluorescence emission wavelength in a wavelength range from 410 to 600 nm. When the compound has the maximum fluorescence emission wavelength in this wavelength range, the compound makes it possible to convert more effectively incident rays having wavelengths which are not easily used (or not usable) for photoelectric conversion by a solar cell into a wavelength range which can be photoelectrically converted by the solar cell. In the invention, the maximum fluorescence emission wavelength denotes a wavelength of a ray showing a maximum emitted quantity, out of light rays emitted from the compound, and is measurable as a wavelength at which the compound shows a maximum emission peak in a fluorescence emission spectrum thereof.

The wavelength-converting encapsulant composition of the present invention includes an optically transparent resin matrix, and the above-defined fluorescent dye compound. When the composition includes the fluorescent dye compound, rays having shorter wavelengths than wavelengths which a solar cell absorbs can be efficiently red-shifted into the range of wavelengths which the solar cell can use for photovoltaics. Consequently, a broader spectrum of solar energy can be converted into electricity. Moreover, the fluorescent dye compound has a large fluorescent quantum efficiency and a good workability, so that the compound can give, advantageously for the production process of the composition and costs, a wavelength-converting encapsulant composition supplying an excellent photoelectric conversion effect. Furthermore, the wavelength-converting encapsulant composition of the invention receives, as an input, at least one photon having a first wavelength to give, as an output, at least one photon having a second wavelength longer (larger) than the first wavelength. In this process, the wavelength-converting encapsulant composition expresses an original function of the composition. Furthermore, even when the wavelength-converting encapsulant composition is subjected to a storage test over a long period, the organic dye compound dispersed in the matrix resin is not precipitated therefrom. Thus, the present invention can easily give a stable and uniform encapsulant composition (and layer). The wavelength-converting encapsulant composition is particularly suitable for solar cells.

It is preferred that the wavelength-converting encapsulant composition includes the fluorescent dye compound in an amount of 0.01 to 10 parts by weight for 100 parts by weight of the resin matrix.

It is preferred in the wavelength-converting encapsulant composition of the present invention that the matrix resin includes, as a main component thereof, an ethylene-vinyl acetate copolymer. When the matrix resin includes, as the main component thereof, the ethylene-vinyl acetate copolymer, this layer can be, with a higher certainty, rendered a wavelength-converting encapsulant layer excellent in light transmittance and endurance.

When the matrix resin is rendered a mixture of plural resins, the wording “AA includes, as a main component thereof, a resin BB” denotes a case where the resin BB is included at a ratio by weight of 50% or more of the AA. The ratio by weight is more preferably 70% or more by weight, even more preferably 90% or more by weight.

Furthermore, the wavelength-converting encapsulant layer of the present invention is formed, using the above-mentioned wavelength-converting encapsulant composition. By the formation using the composition, the composition is turned to a wavelength-converting encapsulant layer which has desired optical properties (such as a high quantum yield) and a good light stability (chemical and physical stability), and which is restrained from being precipitated. In more detail, the fluorescent dye compound has a large fluorescent quantum efficiency and a good workability; thus, the compound can give, advantageously for a production process of the layer and costs, a wavelength-converting encapsulant layer supplying an excellent photoelectric conversion effect. Moreover, the wavelength-converting encapsulant layer of the present invention receives, as an input, at least one photon having a first wavelength to give, as an output, at least one photon having a second wavelength longer (larger) than the first wavelength. In this process, the wavelength-converting encapsulant layer expresses an original function of this layer. Furthermore, even when the wavelength-converting encapsulant layer is subjected to a storage test over a long period, the organic dye compound dispersed in the matrix resin is not precipitated therefrom. Thus, the present invention can easily give a stable and uniform encapsulant composition layer. The wavelength-converting encapsulant layer is particularly suitable for solar cells. Additionally, the wavelength-converting encapsulant layer of the present invention makes use of the above-mentioned wavelength-converting encapsulant composition; accordingly, at the time of the step of curing the wavelength-converting encapsulant composition or the wavelength-converting encapsulant layer, the fluorescent dye can be easily or simultaneously fixed to the composition or layer. Thus, this layer is very good for industrial processes.

The solar cell module of the present invention includes a wavelength-converting encapsulant layer formed using the above-mentioned wavelength-converting encapsulant composition. Since the solar cell module has the wavelength-converting encapsulant layer, the solar cell module is a solar cell module having desired optical properties (such as a high quantum yield) and a good light stability (chemical and physical property). Furthermore, the solar cell module does not cause the fluorescent dye compound to precipitate in a storage test over a long period since the solar cell module has the wavelength-converting encapsulant layer. Thus, the fluorescent dye compound can be restrained from being shifted to a encapsulant layer for a backside surface of the module, or to some other member. The solar cell module is a stable and uniform solar cell module.

It is preferred that the solar cell module of the present invention is configured in such a manner that rays radiated into the module passes through its wavelength-converting encapsulant layer before the rays reach its solar cell. The configuration makes it possible to convert a broader spectrum of solar energy into electricity, with a higher certainty, to heighten the module in photoelectric conversion efficiency.

Furthermore, in the solar cell module of the present invention, the solar cell is preferably a crystal silicon solar cell. By using the solar cell module as a solar cell module in which solar cells as described above are stacked onto each other, the photoelectric efficiency thereof can be more effectively made better. In particular, silicon solar cells have a problem of being low in photoelectric conversion efficiency in the range of wavelengths lower than or equal to a maximum absorption wavelength of silicon, which is 400 nm in an ultraviolet wavelength range. In the present solar cell module, an appropriate use of the above-mentioned fluorescent dye compound, which has an absorption in this wavelength range and can further emit fluorescence at 430 to 530 nm, makes it possible to use light more effectively. If the absorption wavelength range of the fluorescent dye compound is extended into the range of longer wavelengths than the above-mentioned wavelength range, wavelengths which a photoelectric conversion element, such as a solar cell, can originally absorb overlap unfavorably with the absorption wavelengths of the fluorescent dye compound, so that the module may fail in rising in photoelectric conversion efficiency. In the present solar cell module, the use of the above-mentioned fluorescent dye compound makes it possible to control the absorption wavelength of this compound precisely not to cause this problem.

### BRIEF DESCRIPTION OF THE DRAWINGS

FIG. 1 illustrates an example of a solar cell module in which a encapsulant layer of the present invention for solar cells is used.

FIG. 2 illustrates an example of the solar cell module, in which the encapsulant layer of the present invention for solar cells is used.

### MODE FOR CARRYING OUT THE INVENTION

Hereinafter, embodiments of the present invention will be described.

### (Fluorescent Dye Compound)

The fluorescent dye compound of the present invention is a compound represented by the following general formula (I):

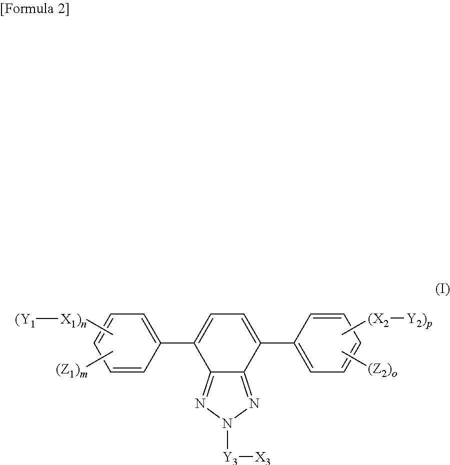

wherein X₁(s) and X₂(s) each independently represent —O—, —(C═O) O—, —O(C═O)—, —CH₂O—, —CH₂O(CO)—, —NH(CO)—, —NR—CH₂—, or a single bond wherein R represents an alkyl group having 1 to 8 carbon atoms;

X₃ represents a group containing a carbon-carbon double bond, or hydrogen;

Y₁(s) and Y₂(s) each independently represent an optionally-substituted alkyl group having 1 to 18 carbon atoms, or an optionally-substituted alkyl group having a carbon-carbon double bond and having 2 to 18 carbon atoms (provided that one or two out of any nonadjacent two of the carbon atoms in the alkyl group may (each) be substituted with an oxygen atom);

Y₃ represents an optionally-substituted alkyl group having 1 to 18 carbon atoms, an optionally-substituted aryl group having 5 to 18 carbon atoms, or an optionally-substituted alkyl group having a carbon-carbon double bond and having 2 to 18 carbon atoms (provided that one or two out of any nonadjacent two of the carbon atoms in the alkyl group may (each) be substituted with an oxygen atom);

Z₁(s) and Z₂(s) each independently represent an optionally-substituted alkyl group having 1 to 18 carbon atoms (provided that one or two out of any nonadjacent two of the carbon atoms in the alkyl group may (each) be substituted with an oxygen atom), an optionally-substituted alkoxy group having 1 to 18 carbon atoms (provided that one or two out of any nonadjacent two of the carbon atoms in the alkoxy group may (each) be substituted with an oxygen atom), a fluoro group, a cyano group, —COOR¹ group, —NHCOR² group, or a hydroxyl group wherein R¹ and R² each represent an alkyl group having 1 to 18 carbon atoms or a phenyl group; and

m, n, o and p each independently represent an integer of 0 to 4 (provided that m+n is 4 or less, and o+p is 4 or less), and when m, n, o or p is 2 or more, the plural substituents concerned may be the same as or different from each other.

A useful nature of fluorescent (or photo-luminescent) dyes is that these dyes can absorb photons of a light ray having a specified wavelength and can further re-emit the photons with a different wavelength. This phenomenon makes these dyes useful for photoelectromotive industries.

A chromophore represented by the general formula (I) is useful for a fluorescent dye (fluorescent dye compound) in the application of the dye to various articles such as wavelength-converting films. As illustrated in the general formula (I), this dye is a benzo heterocyclic compound, more specifically, a novel compound having a benzotriazole structure (benzotriazole derivative). More details and actual examples related to usable types of the compound will be described below although the description does not limit the scope of the invention. As far as the effects and advantages of the invention are not hindered, the scope of the fluorescent dye compound of the present invention also includes any compound in which any atom of the benzotriazole ring of this dye compound is substituted.

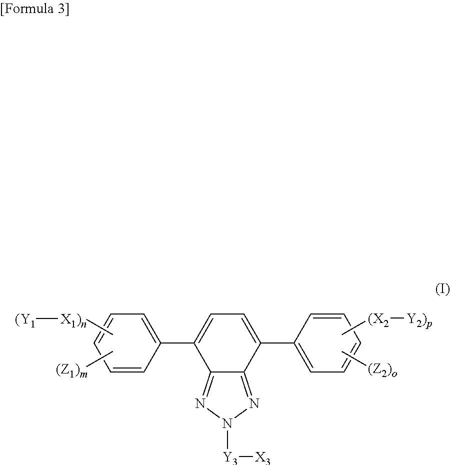

wherein X₁(s) and X₂(s) each independently represent —O—, —(C═O)O—, —O(C═O)—, —CH₂O—, —CH₂O(CO)—, —NH(CO)—, —NR—CH₂—, or a single bond wherein R represents an alkyl group having 1 to 8 carbon atoms;

X₃ represents a group containing a carbon-carbon double bond, or hydrogen;

Y₁(s) and Y₂(s) each independently represent an optionally-substituted alkyl group having 1 to 18 carbon atoms, or an optionally-substituted alkyl group having a carbon-carbon double bond and having 2 to 18 carbon atoms (provided that one or two out of any nonadjacent two of the carbon atoms in the alkyl group may (each) be substituted with an oxygen atom);

Y₃ represents an optionally-substituted alkyl group having 1 to 18 carbon atoms, an optionally-substituted aryl group having 5 to 18 carbon atoms, or an optionally-substituted alkyl group having a carbon-carbon double bond and having 2 to 18 carbon atoms (provided that one or two out of any nonadjacent two of the carbon atoms in the alkyl group may (each) be substituted with an oxygen atom);

one or more of the symbols Y₁(s), Y₂ (s), Y₃ and X₃ (each) have a carbon-carbon double bond;

Z₁(s) and Z₂(s) each independently represent an optionally-substituted alkyl group having 1 to 18 carbon atoms (provided that one or two out of any nonadjacent two of the carbon atoms in the alkyl group may (each) be substituted with an oxygen atom), an optionally-substituted alkoxy group having 1 to 18 carbon atoms (provided that one or two out of any nonadjacent two of the carbon atoms in the alkoxy group may (each) be substituted with an oxygen atom), a fluoro group, a cyano group, —COOR¹ group, —NHCOR² group, or a hydroxyl group wherein R¹ and R² each represent an alkyl group having 1 to 18 carbon atoms or a phenyl group; and

m, n, o and p each independently represent an integer of 0 to 4 (provided that m+n is 4 or less, and o+p is 4 or less), and when m, n, o or p is 2 or more, the plural substituents concerned may be the same as or different from each other.

Since the benzotriazole derivative has the structure represented by the general formula (I), the derivative can be an excellent fluorescent dye compound having a high workability, desired optical properties (such as a high quantum yield), and a good light stability (chemical and physical stability). When this derivative, particularly, forms a chemical bond to a matrix resin through at least one of Y₁(s), Y₂(s), Y₃ and X₃ (by, e.g., radical crosslinkage, nucleophilic substitution reaction, addition reaction or radial polymerization), the organic dye compound dispersed in the matrix resin can easily give a stable and uniform encapsulant composition (and layer) without being precipitated even in a long-term storage test. Furthermore, the benzotriazole derivative is favorably usable as a monomer for the fluorescent dye compound since the benzotriazole derivative has the structure represented by the general formula (I).

In the benzotriazole derivative, the symbols X₁(s) and X₂(s) each independently represent —O—, —(C═O)O—, —O(C═O)—, —CH₂O—, —CH₂O(CO)—, —NH(CO)—, —NR—CH₂—, or a single bond. R represents an alkyl group having 1 to 8 carbon atoms. At least one of X₁(s) and X₂(s) is in particular preferably —(C═O)O—, or —O(CO)—. A case where X₁(s) or X₂(s) is/are (each) a single bond denotes that Y(s) is/are (each) bonded directly to the benzene ring concerned.

In the benzotriazole derivative, Y₁(s) and Y₂(s) each independently represent an optionally-substituted alkyl group having 1 to 18 carbon atoms; an optionally-substituted alkyl group having a carbon-carbon double bond and having 2 to 18 carbon atoms (provided that one or two out of any nonadjacent two of the carbon atoms in the alkyl group may (each) be substituted with an oxygen atom); or an optionally-substituted alkyl group having a carbon-carbon triple bond and having 2 to 18 carbon atoms (provided that one or two out of any nonadjacent two of the carbon atoms in the alkyl group may (each) be substituted with an oxygen atom). The number of carbon atoms of each of the alkyl groups described herein is preferably from 1 to 18, more preferably from 2 to 8.

Examples of each of the symbols Y₁(s) and Y₂(s) include ethyl, propyl, isopropyl, butyl, isobutyl, pentyl, hexyl, heptyl, 2-ethylhexyl, octyl, ethynyl, propenyl, isopropenyl, butenyl, isobutenyl, pentenyl, hexenyl, heptenyl, 2-ethylhexenyl, octenyl, 3-allyloxy-2-hydroxypropyl, and 3-allyloxy-2-acetoxypropyl. However, each of Y₁(s) and Y₂(s) is not limited to these examples. These groups may be used singly or in the form of any mixture of two or more thereof.

About each of Y₁(s) and Y₂(s), at least one of Y₁(s) and Y₂(s) is preferably, for example, an allyl group, a group obtained by removing a carbonyl group from an oleyl group, or a group obtained by removing a carbonyl group from a linolenic group. For example, the group obtained by removing a carbonyl group from an oleyl group denotes a chemical structure of a moiety obtained by removing, from the chemical structure of an oleyl group, the terminal carbonyl group (—(C═O)) thereof. In other words, when the chemical structure of an oleyl group is represented by, e.g., an R—CO-structure, the group obtained by removing a carbonyl group from an oleyl group denotes an R-group. In the same manner, when the chemical structure of an oleic acid is represented by, e.g., an R—COOH structure, a group obtained by removing a carbonyl group from an oleyl group denotes a structure identical with a structure (i.e., an R-group) obtained by removing a carboxylic acid residue from oleic acid.

In the benzotriazole derivative, the symbol Y₃ represents an optionally-substituted alkyl group having 1 to 18 carbon atoms; an optionally-substituted aryl group having 5 to 18 carbon atoms; an optionally-substituted alkyl group having a carbon-carbon double bond and having 2 to 18 carbon atoms (provided that one or two out of any nonadjacent two of the carbon atoms in the alkyl group may (each) be substituted with an oxygen atom); or an optionally-substituted alkyl group having a carbon-carbon triple bond and having 2 to 18 carbon atoms (provided that one or two out of any nonadjacent two of the carbon atoms in the alkyl group may (each) be substituted with an oxygen atom). The number of carbon atoms of each of the alkyl groups described herein is preferably from 1 to 18, more preferably from 2 to 8. The number of carbon atoms of the above-mentioned aryl group is preferably from 6 to 12, more preferably from 8 to 10.

Examples of Y₃ include ethyl, propyl, isopropyl, butyl, isobutyl, pentyl, hexyl, heptyl, 2-ethylhexyl, octyl, phenyl, methylphenyl, dimethylphenyl, trimethylphenyl, tetramethylphenyl, ethylphenyl, diethylphenyl, n-propylphenyl, di-n-propylphenyl, isopropylphenyl, diisopropylphenyl, n-butylphenyl, di-n-butylphenyl, isopropylphenyl, sec-butylphenyl, di-sec-butylphenyl, t-butylphenyl, di-t-butylphenyl, diisopropylphenyl, naphthyl, biphenyl, phenanthryl, pyrrolyl, furanyl, thiophenyl, imidazolyl, pyrazolyl, oxazolyl, thiazolyl, pyrazinyl, ethenyl, propenyl, isopropenyl, butenyl, isobutenyl, pentenyl, hexenyl, heptenyl, 2-ethylhexenyl, octenyl, 3-allyloxy-2-hydroxypropyl, and 3-allyloxy-2-acetoxypropyl. However, Y₃ is not limited to these examples. These groups may be used singly or in the form of any mixture of two or more thereof.

Y₃ is preferably, for example, a vinyl group, an allyl group, a group obtained by removing a carbonyl group from an oleyl group, a group obtained by removing a carbonyl group from a linolic group, or a group obtained by removing a carbonyl group from a linolenic group. For example, the group obtained by removing a carbonyl group from an oleyl group denotes a chemical structure of a moiety obtained by removing, from the chemical structure of an oleyl group, the terminal carbonyl group (—(C═O)) thereof. In other words, when the chemical structure of an oleyl group is represented by, e.g., an R—CO-structure, the group obtained by removing a carbonyl group from an oleyl group denotes an R-group. In the same manner, when the chemical structure of an oleic acid is represented by, e.g., an R—COOH structure, a group obtained by removing a carbonyl group from an oleyl group denotes a structure identical with a structure (i.e., an R-group) obtained by removing a carboxylic acid residue from oleic acid. When X₃ is, for example, hydrogen, —Y₃—X₃ is, for example, a vinyl or allyl group.

In the benzotriazole derivative, the symbol X₃ is preferably —CR′═CH₂, —(C═O)O—CR′═CH₂, —O(C═O)—CR′═CH₂, —CH₂O(CO)—CR′═CH₂, —NH(CO)—CR′═CH₂, or —NR—CH₂—CR′═CH₂. When this derivative has a reactive vinyl-group-containing group, such as the structure described just above, it becomes easy that the derivative forms a chemical bond through the X₃ group to the matrix resin, particularly, a bond through the X₃ group to the resin by, e.g., radical crosslinkage, or radical polymerization reaction.

Examples of X₃ include ethenyl, propenyl, isopropenyl, butenyl, isobutenyl, pentenyl, hexenyl, heptenyl, 2-ethylhexenyl, octenyl, 3-allyloxy-2-hydroxypropyl, 3-allyloxy-2-acetoxypropyl, acryloyl, and methacryloyl groups. However, X₃ is not limited to these examples.

In the benzotriazole derivative, Z₁(s) and Z₂(s) each independently represent an optionally-substituted alkyl group having 1 to 18 carbon atoms (provided that one or two out of any nonadjacent two of the carbon atoms in the alkyl group may (each) be substituted with an oxygen atom), an optionally-substituted alkoxy group having 1 to 18 carbon atoms (provided that one or two out of any nonadjacent two of the carbon atoms in the alkoxy group may (each) be substituted with an oxygen atom), a fluoro group, a cyano group, —COOR¹ group, —NHCOR² group, or a hydroxyl group wherein R¹ and R² each represent an alkyl group having 1 to 18 carbon atoms or a phenyl group; and m, n, o and p each independently represent an integer of 0 to 4 (provided that m+n is 4 or less, and o+p is 4 or less). The symbols m, n, o and p each independently represent an integer of 0 to 4. The number of carbon atoms of each of the alkyl groups described herein is preferably from 1 to 18, more preferably from 1 to 12, even more preferably from 1 to 8. The number of carbon atoms of the alkoxy group is preferably from 1 to 18, more preferably from 1 to 12, even more preferably from 1 to 8. When m, n, o or p is 2 or more, the plural substituents concerned may be the same as or different from each other.

Examples of the alkyl group as each of Z₁(s) and Z₂(s) include methyl, ethyl, propyl, isopropyl, butyl, isobutyl, sec-butyl, tert-butyl, pentyl, hexyl, heptyl, 2-ethylhexyl, and octyl. However, the alkyl group is not limited to these examples. One or two out of any nonadjacent two of the carbon atoms in the alkyl group may (each) be substituted with an oxygen atom.

The alkoxy group as each of Z₁(s) and Z₂ (s) may be a linear or branched alkyl group bonded covalently to the parent molecule through a linkage —O—. Examples of the alkoxy group as each of Z₁(s) and Z₂(s) include methoxy, ethoxy, propoxy, isopropoxy, butoxy, n-butoxy, sec-butoxy, tert-butoxy, pentyloxy, hexyloxy, heptyloxy, 2-ethylhexyloxy, octyloxy, 1-propenyloxy, 2-propenyloxy, butenyloxy, pentenyloxy, hexenyloxy, heptenyloxy, octenyloxy, 3-allyloxy-2-hydroxypropyloxy and 3-allyloxy-2-acetoxypropyloxy. However, the alkoxy group is not limited to these examples. One or two out of any nonadjacent two of the carbon atoms in the alkoxy group may (each) be substituted with an oxygen atom.

The fluoro group as each of Z₁(s) and Z₂(s) may be a group in which hydrogens of an alkyl group are partially or wholly substituted with one or more fluorine atoms. Examples of the fluoro group as each of Z₁(s) and Z₂(s) include trifluoromethyl, and pentafluoroethyl groups. However, the fluoro group is not limited to these groups.

The —COOR group as each of Z₁(s) and Z₂(s) may be a group having an alkyl ester structure. Examples of the —COOR¹ group as each of Z₁(s) and Z₂(s) include methyl ester, ethyl ester, 1-propyl ester, 2-propyl ester, and phenyl ester groups. However, the —COOR¹ group is not limited to these examples.

The —NHCOR² group as each of Z₁(s) and Z₂ (s) may be a group having an acylamide structure. Examples of the —NHCOR² group as each of Z₁(s) and Z₂(s) include an acetylamide group, and propionic amide. However, the —NHCOR² group is not limited to these examples.

The symbols m, n, o and p each independently represent an integer of 0 to 4. Specifically, m, n, o and p may each be a value of 0, 1, 2, 3 or 4 provided that m+n is 4 or less, and o+p is 4 or less.

When the word “substituted group” is used in the present specification, the substituted group originates an unsubstituted parent structure in which one or more hydrogen atoms are substituted with one or more different atoms or groups. When the hydrogen(s) concerned is/are substituted, the (one or more) substituents are one or more groups that are individually and independently selected from, for example, the following: C₁-C₆ alkyl, C₁-C₆ alkenyl, C₁-C₆ alkynyl, C₃-C₇ cycloalkyl (which is optionally-substituted with one or more of halo, alkyl, alkoxy, carboxyl, haloalkyl, CN, —SO₂-alkyl, —CF₃, and —OCF₃), cycloalkyl geminally attached, C₁-C₆ heteroalkyl, C₃-C₁₀ heterocycloalkyl (such as tetrahydrofuryl) (which is optionally-substituted with one or more of halo, alkyl, alkoxy, carboxyl, CN, —SO₂-alkyl, —CF₃, and —OCF₃), aryl (which is optionally-substituted with one or more of halo, alkyl, aryl that is optionally-substituted with C₁-C₆ alkyl, arylalkyl, alkoxy, aryloxy, carboxyl, amino, imide, amide (carbamoyl), optionally-substituted cyclic imide, cyclic amide, CN, —NH—C(═O)-alkyl, —CF₃, and —OCF₃), arylalkyl (which is optionally-substituted with one or more of halo, alkyl, alkoxy, aryl, carboxyl, CN, —SO₂-alkyl, —CF₃, and —OCF₃), heteroaryl (which is optionally-substituted with one or more of halo, alkyl, alkoxy, aryl, heteroaryl, aralkyl, carboxyl, CN, —SO₂-alkyl, —CF₃, and —OCF₃), halo (such as chloro, bromo, iodo, or fluoro), cyano, hydroxy, optionally-substituted cyclic imide, amino, imide, amide, —CF₃, C₁-C₆ alkoxy, aryloxy, acyloxy, sulfhydryl (mercapto), halo(C₁-C₆) alkyl, C₁-C₆ alkylthio, arylthio, mono (C₁-C₆)alkylamino, di (C₁-C₆)alkylamino, quaternary ammonium salts, amino(C₁-C₆)alkoxy, hydroxy(C₁-C₆)alkylamino, amino (C₁-C₆) alkylthio, cyanoamino, nitro, carbamoyl, keto(oxy), carbonyl, carboxy, glycolyl, glycyl, hydrazino, guanyl, sulfamyl, sulfonyl, sulfinyl, thiocarbonyl, thiocarboxy, sulfonamide, ester, C-amide, N-amide, N-carbamate, O-carbamate, and urea groups; and any combination of two or more thereof. When any one of the substituents is described as “optionally-substituted” substituent, the substituent may always be substituted with a substituent as described above.

The property of the fluorescent dye in the present invention is not limited only to the property that it is sufficient for the dye to absorb a light ray in a specified wavelength range and further convert the wavelength of the absorbed ray to a longer wavelength to emit the longer wavelength ray. It is preferred that the fluorescent dye in the present application shows no absorption (or less shows an absorption) at longer wavelengths than the maximum absorption wavelength of the dye if possible. About an index thereof, for example, it is desired that the absorbance of the dye at a wavelength 60 nm longer than the maximum absorption wavelength is smaller than the absorbance thereof at the maximum absorption wavelength.

As a method for synthesizing the above-mentioned fluorescent dye compound, a known synthesizing method is appropriately usable. Examples of the synthesizing method include a method of causing a bi-substituted benzotriazole obtained by substituting leaving groups of, e.g., 4,7-dibromobenztriazole (the bi-substituted benzotriazole=halogenated benzotriazole) to undergo a coupling reaction with a phenylboronic acid which contains one or more X-Y side-chains (Y₁-X₁ and/or Y₂-X₂); a method of bonding a compound corresponding to a precursor of a phenyl group which contains one or more X-Y side-chains onto the bi-substituted benzotriazole by, e.g., nucleophilic substitution reaction; a method of bonding hydroxyphenylboronic acid onto the bi-substituted benzotriazole, subsequently converting the hydroxyl groups to, e.g., alkoxy groups or ester groups, and then introducing one or more X—Y groups to the resultant; a method of using a metallic catalyst to attain the coupling; a method of converting alkoxy groups as the side chains partially to carbon-carbon double bonds; and a method in which at a time before or after the introduction of the X-Y side chain(s), or at a time simultaneous with the introduction, one or more Y₃-X₃ groups (or one or more precursor groups thereof) are introduced to the compound concerned.

For example, the following methods are given as particularly preferred and easy methods: a method of esterifying, with an unsaturated acid such as oleic acid, a hydroxyphenylbenzotriazole derivative in which a benzene ring adjacent to a benzotriazole skeleton has a phenolic hydroxyl group, thereby being condensed with the acid (in which a condensing agent may be appropriately used); a method of esterifying, with an unsaturated aliphatic alcohol, a carboxyphenylbenzotriazole derivative in which a benzene ring adjacent to a benzotriazole skeleton has a carboxyl group, thereby being condensed with the alcohol (in which a condensing agent may be appropriately used); and a method of using an alkylation reaction to link a halide or glycidyl compound which has an unsaturated bond to a hydroxyphenylbenzotriazole derivative in which a benzene ring adjacent to a benzotriazole skeleton has a phenolic hydroxyl group.

### (Light Wavelength-Converting Organic Compound)

The light wavelength-converting organic compound of the present invention is fixable to a polymer matrix through a chemical bond.

About the light wavelength-converting organic compound, it is sufficient for the fixation through the chemical bond to be attained to such a degree that the fluorescent dye can be hindered from being shifted in the matrix. For the fixation through the chemical bond, a known technique may be appropriately used. From the viewpoint of bond-stability, and the stability over time, fixation based on a covalent bond is preferred.

The light wavelength-converting organic compound is preferably fixable through a crosslinking reaction, cyclization reaction, substitution reaction or polymerization reaction. The fixation by use of the reaction makes it possible to form the chemical bond, particularly, the covalent bond.

The light wavelength-converting organic compound is preferably a benzotriazole derivative. The fluorescent dye compound represented by the general formula (I) is in particular preferably usable as the light wavelength-converting organic compound of the present invention.

In the light wavelength-converting organic compound, the polymer matrix includes, as a main component thereof, an ethylene-vinyl acetate copolymer.

### (Wavelength-Converting Encapsulant Composition)

The wavelength-converting encapsulant composition of the present invention has a wavelength-converting function. The wavelength-converting encapsulant composition is preferably a composition for converting the wavelength of a light ray radiated into this composition into a longer wavelength. The wavelength-converting encapsulant composition can be produced, for example, by dispersing a fluorescent dye compound having a wavelength-converting function, and others into an optically transparent matrix resin.

The method for dispersing (and/or fixing) the fluorescent dye compound may be, for example, a method of polymerizing the fluorescent dye compound partially or wholly together with the monomer component from which the matrix resin is produced (copolymerization reaction method); or a method of forming covalent bonds and introducing the covalent bonds appropriately into the matrix polymer that has been already produced or partially produced (addition-manner introduction method). These methods can each be attained by bond-formation using mainly the carbon-carbon bond moiety in the general formula (I).

When the copolymerization reaction is conducted, a known polymer-synthesizing method is appropriately usable. The method is, for example, a method of subjecting the monomer of the general formula (I) according to the present invention, and a different monomer to random-, graft-, cross-, or block-copolymerization. The copolymerization reaction makes use of, e.g., radical polymerization (cation, anion, each living, and others), ion polymerization, addition polymerization (polyaddition), condensation polymerization (polycondensation), cyclization polymerization, or ring-opening polymerization. The copolymerization reaction makes use of, e.g., a synthesis manner in an organic solvent system or aqueous solution system, or in an emulsion state or suspension state.

Examples of the different monomer include acrylic acid, methacrylic acid, methyl acrylate, methyl methacrylate, ethyl acrylate, ethyl methacrylate, butyl acrylate, butyl methacrylate, 2-ethylhexyl acrylate, 2-ethylhexyl methacrylate, any other alkyl (meth)acrylate, cyclohexyl acrylate, cyclohexyl methacrylate, phenyl acrylate, phenyl methacrylate, benzyl acrylate, benzyl methacrylate, styrene, α-methylstyrene, vinyltoluene, acrylamide, diacetoneacrylamide, acrylonitrile, methacrylonitrile, maleic anhydride, phenylmaleimide, and cyclohexylmaleimide. Other examples thereof include any alkyl (meth)acrylate in which the alkyl group is substituted with, e.g., a hydroxyl group, an epoxy group, or a halogen radical. About the alkyl (meth)acrylate, the number of carbon atoms of the alkyl group of the ester moiety therein is preferably from 1 to 18, more preferably from 1 to 8 carbon atoms. These compounds may be used singly, or in the form of a mixture of two or more thereof.

At the time of conducting the copolymerization reaction, about the fluorescent dye compound, the monomer of the general formula (III), or any other monomer having a benzotriazole structure is used preferably in an amount of 0.01 to 10 parts by weight for 100 parts by weight of the entire monomer components. The monomer may be used in an amount of 0.02 to 5 parts by weight, or in an amount of 0.05 to 3 parts by weight.

At the time of conducting the copolymerization reaction, the polymerization can be attained, for example, by adding a thermopolymerization initiator or photopolymerization initiator to the monomer components, and then heating the resultant or radiating light to the resultant.

The thermopolymerization initiator may be an appropriate known peroxide. Examples of the polymerization initiator include 2,5-dimethylhexane-2,5-dihydroperoxide, 2,5-dimethyl-2,5-di(t-butylperoxy)hexane-3, di-t-butylperoxide, dicumylperoxide, 2,5-dimethyl-2,5-di(t-butylperoxy)hexane, dicumylperoxide, α,α′-bis(t-butylperoxyisopropyl)benzene, n-butyl-4,4-bis(t-butylperoxy)butane, 2,2-bis(t-butylperoxy)butane, 1,1-bis(t-butylperoxy)cyclohexane, 1,1-bis(t-butylperoxy)3,3,5-trimethylcyclohexane, t-butyl peroxybenzoate, and benzoylperoxide. These compounds may be used singly, or in the form of a mixture of two or more thereof.

The blend amount of the thermopolymerization initiator may be, for example, in an amount of 0.1 to 5 parts by weight for 100 parts by weight of the monomer components.

The above-mentioned photopolymerization initiator may be an appropriate known photopolymerization initiator that produces free radicals by ultraviolet rays or visible rays. Examples of the photopolymerization initiator include benzoin ethers such as benzoin methyl ether, benzoin ethyl ether, benzoin isopropyl ether, benzoin isobutyl ether, and benzoin phenyl ether; benzophenones such as benzophenone, N,N′-tetramethyl-4,4′-diaminobenzophenone (Michler's ketone) and N,N′-tetraethyl-4,4′-diaminobenzophenone; benzyl ketals such as benzyl dimethyl ketal (IRGACURE 651, manufactured by Ciba Japan K.K.), and benzyl diethyl ketal; acetophenones such as 2,2-dimethoxy-2-phenylacetophenone, p-tert-butyldichloroacetophenone, and p-dimethylaminoacetophenone; xanthones such as 2,4-dimethylthioxanthone, and 2,4-diisopropylthioxanthone; and hydroxycyclohexyl phenyl ketone (IRGACURE 184, manufactured by Ciba Specialty Chemicals, Inc.), 1-(4-isopropylphenyl)-2-hydroxy-2-methylpropane-1-one (DAROCURE 1116, manufactured by Ciba Japan K.K.), and 2-hydroxy-2-methyl-1-phenylpropane-1-one (DAROCURE 1173, manufactured by Merck & Co., Inc.). These initiators may be used singly, or in the form of a mixture of two or more thereof.

The photopolymerization initiator may be, for example, a combination of a 2,4,5-triallylimidazole dimer with 2-mercaptobenzoxazole, leuco crystal violet, or tris(4-diethylamino-2-methylphenyl)methane. A known additive, for example, tertiary amine such as triethanolamine for benzophenone may be appropriately used.

The blend amount of the photopolymerization initiator may be, for example, from 0.1 to 5 parts by weight for 100 parts by weight of the monomer components.

When the above-mentioned addition-manner introduction method is conducted, a known organic synthesis method is appropriately usable. The method is, for example, a method of subjecting the fluorescent dye compound of the general formula (I) according to the present invention to, e.g., a condensation reaction, addition reaction or substitution reaction to form covalent bonds. Furthermore, the method may be, for example, a method of introducing the fluorescent dye compound into an already produced polymer (or oligomer) to produce the form of the so-called pendant to a main chain skeleton of the polymer; or a method of introducing the fluorescent dye compound into, e.g., a terminal of the main chain skeleton of the polymer to produce the form of an endcap onto the terminal.

These addition-manner introduction methods can each be attained by bond-formation using mainly the carbon-carbon double bond moiety in the general formula (I).

In the addition-manner introduction method, as the polymer having the already-formed polymer structure, an optically transparent matrix resin is preferably used.

More specifically, the matrix resin is selected from the viewpoint of translucency, workability, weather resistance, light resistance and others. The resin may be an ethylene-vinyl ester copolymer, a typical example thereof being EVA; an ethylene-unsaturated carboxylic acid copolymer such as ethylene-(meth)acrylic acid copolymer; an ethylene-unsaturated carboxylic acid ester copolymer such as ethylene-(meth)acrylate copolymer; or an unsaturated carboxylic acid ester polymer such as polymethyl methacrylate. Alternatively, the matrix resin may be, for example, a fluororesin such as vinylidene fluoride resin, or polyethylene tetrafluoroethylene; a polyolefin, for example, a polyethylene (PE) such as low-density polyethylene (LDPE) or linear low-density polyethylene (LLDPE, typically, an LLDPE that can be produced using, e.g., a Ziegler catalyst, a vanadium catalyst, or a metallocene catalyst; a polypropylene (PP, for example, a PP that can be produced using, e.g., a Ziegler catalyst, a Phillips catalyst, or a metallocene catalyst), a polyvinyl alcohol (for example, POVAL, manufactured by Kuraray Co., Ltd.), an ethylene-vinyl alcohol copolymer (for example, EVAL, manufactured by Kuraray Co., Ltd.), an ethylene/α-olefin copolymer that can be produced using, e.g., a Ziegler catalyst, a vanadium catalyst, or a metallocene catalyst, or any modified thereof (modified polyolefin); polybutadiene; a polyvinyl acetate such as polyvinyl formal, polyvinyl butyral (PVB resin), or modified PVB; polyethylene terephthalate (PET); polyimide; amorphous polycarbonate; siloxane sol-gel; polyurethane; polystyrene; polyethersulfone; polyarylate; epoxy resin; silicone resin; or ionomer. These resins may be used singly, or in the form of a mixture of two or more thereof. More details are presented below.

Examples of the above-mentioned poly(meth)acrylate include polyacrylate and polymethacrylate, an example of which is (meth)acrylate resin. Examples of the polyolefin resin include polyethylene, polypropylene, and polybutadiene. Examples of the polyvinyl acetate include polyvinyl formal, polyvinyl butyral (PVB resin), and modified PVB.

Examples of a constituent monomer for the (meth)acrylate resin described just above include alkyl (meth)acrylates such as methyl acrylate, methyl methacrylate, ethyl acrylate, ethyl methacrylate, butyl acrylate, butyl methacrylate, 2-ethylhexyl acrylate, and 2-ethylhexyl methacrylate; and cyclohexyl acrylate, cyclohexyl methacrylate, phenyl acrylate, phenyl methacrylate, benzyl acrylate, and benzyl methacrylate. The constituent monomer may also be any alkyl (meth)acrylate in which any one of the alkyl groups described just above is substituted with, e.g., a hydroxyl group, an epoxy group, or a halogen radical. These compounds may be used singly, or in the form of a mixture of two or more thereof.

In these (meth)acrylates, the number of carbon atoms of the alkyl group in their ester moiety is preferably from 1 to 18, more preferably from 1 to 8.

The above-mentioned (meth)acrylate resin may be rendered a copolymer by using, besides any one of the (meth)acrylates, an unsaturated monomer copolymerizable with the (meth)acrylate.

Examples of the unsaturated monomer include unsaturated organic acids such as methacrylic acid and acrylic acid, styrene, α-methylstyrene, acrylamide, diacetoneacrylamide, acrylonitrile, methacrylonitrile, maleic anhydride, phenylmaleimide, and cyclohexylmaleimide. These unsaturated monomers may be used singly, or in the form of a mixture of two or more thereof.

Out of the (meth)acrylates, particularly preferred are methyl acrylate, ethyl acrylate, isobutyl acrylate, n-butyl acrylate, 2-ethylhexyl acrylate, methyl methacrylate, isobutyl methacrylate, n-butyl methacrylate, and 2-ethylhexyl methacrylate; and any alkyl (meth)acrylate in which the functional group of any one of these (meth)acrylates is substituted. Methyl methacrylate is a more preferred example from the viewpoint of durability and versatility.

The copolymer made from the (meth)acrylate and the unsaturated monomer is, for example, (meth)acrylate-styrene copolymer, or ethylene-vinyl acetate copolymer. Out of these examples, ethylene-vinyl acetate copolymer is preferred from the viewpoint of moisture resistance and versatility, and costs. Moreover, any (meth)acrylate is preferred from the viewpoint of durability and surface hardness. Furthermore, from the above-mentioned individual viewpoints, it is preferred to use the ethylene-vinyl acetate copolymer and the (meth)acrylate in combination.

About the ethylene-vinyl acetate copolymer, the content by proportion of the vinyl acetate units is from 10 to 35 parts by weight, more preferably from 20 to 30 parts by weight for 100 parts by weight of the ethylene-vinyl acetate copolymer. Any one of these contents by proportion is preferred from the viewpoint of a uniform dispersibility of, e.g., a rare earth complex into the matrix resin.

When the ethylene-vinyl acetate copolymer is used as the optically transparent matrix resin, a commercially available product is fittingly usable. Examples of the commercially available product of the ethylene-vinyl acetate copolymer include ULTRACENE (manufactured by Tosoh Corp.), EVAFLEX (manufactured by Du Pont-Mitsui Polychemicals Co., Ltd.), SUNTEC EVA (manufactured by Asahi Kasei Chemicals Corp.), UBE EVA copolymer (manufactured by Ube-Maruzen Polyethylene Co., Ltd.), EVATATE (manufactured by Sumitomo Chemical Co., Ltd.), NOVATEC EVA (manufactured by Japan Polyethylene Corp.), SUMITATE (manufactured by Sumitomo Chemical Co., Ltd.), and NIPOFLEX (manufactured by Tosoh Corp.).

A crosslinking monomer may be added to the matrix resin to render the resin a resin having a crosslinked structure.

Examples of the crosslinking monomer include dicyclopentenyl (meth)acrylate, tetrahydrofurfuryl (meth)acrylate, benzyl (meth)acrylate, compounds each obtained by causing an α,β-unsaturated carboxylic acid to react with a polyhydric alcohol (for example, polyethylene glycol di(meth)acrylate (the number of ethylene groups: 2 to 14), trimethylolpropane di(meth)acrylate, trimethylolpropane tri(meth)acrylate, trimethylolpropane ethoxytri(meth)acrylate, trimethylolpropane propoxytri(meth)acrylate, tetramethylolmethane tri (meth)acrylate, tetramethylolmethane tetra (meth)acrylate, polypropylene glycol di (meth)acrylate (the number of propylene groups: 2 to 14), dipentaerythritol penta(meth)acrylate, dipentaerythritol hexa(meth)acrylate, bisphenol A polyoxyethylene di(meth)acrylate, bisphenol A dioxyethylene di(meth)acrylate, bisphenol Atrioxyethylene di(meth)acrylate, and bisphenol A decaoxyethylene di(meth)acrylate), compounds each obtained by adding an α,β-unsaturated carboxylic acid to a glycidyl-group-containing compound (for example, trimethylolpropane triglycidyl ether triacrylate, and bisphenol A diglycidyl ether diacrylate), esterified products each made from a polybasic carboxylic acid (such as phthalic anhydride) and a substance having a hydroxyl group and an ethylenical unsaturated group (such as β-hydroxyethyl (meth)acrylate), alkyl esters of acrylic acid or methacrylic acid (for example, methyl (meth)acrylate, ethyl (meth)acrylate, butyl (meth)acrylate, and 2-ethylhexyl (meth)acrylate), and urethane (meth)acrylates (for example, a reactant made from tolylene diisocyanate and 2-hydroxyethyl (meth)acrylate, and a reactant made from trimethylhexamethylene diisocyanate, cyclohexanedimethanol, and 2-hydroxyethyl (meth)acrylate). These crosslinking monomers may be used singly, or in the form of a mixture of two or more thereof. Out of these crosslinking monomers, preferred are trimethylolpropane tri (meth)acrylate, dipentaerythritol tetra(meth)acrylate, dipentaerythritol hexa(meth)acrylate, and bisphenol A polyoxyethylene dimethacrylate.

When the matrix resin containing the crosslinking resin is used, a crosslinked structure can be formed, for example, by adding the thermopolymerization initiator or photopolymerization initiator to the crosslinking monomer, and then heating the resultant or radiating light to the resultant to be polymerized and crosslinked. The polymerization initiator can contribute to the formation of a crosslinked structure of the fluorescent dye compound and the matrix resin through the carbon-carbon double or triple bond of this dye compound according to circumstances.

The thermopolymerization initiator may be an appropriate known peroxide. Examples of the thermopolymerization initiator include 2,5-dimethylhexane-2,5-dihydroperoxide, 2,5-dimethyl-2,5-di(t-butylperoxy)hexane-3, di-t-butylperoxide, dicumylperoxide, 2,5-dimethyl-2,5-di(t-butylperoxy)hexane, dicumylperoxide, α,α′-bis(t-butylperoxyisopropyl)benzene, n-butyl-4,4-bis(t-butylperoxy)butane, 2,2-bis(t-butylperoxy)butane, 1,1-bis(t-butylperoxy)cyclohexane, 1,1-bis(t-butylperoxy)3,3,5-trimethylcyclohexane, t-butyl peroxybenzoate, and benzoylperoxide. These compounds may be used singly, or in the form of a mixture of two or more thereof.

The blend amount of the thermopolymerization initiator may be, for example, in an amount of 0.1 to 5 parts by weight for 100 parts by weight of the matrix resin.

The above-mentioned photopolymerization initiator may be an appropriate known photopolymerization initiator that produces free radicals by ultraviolet rays or visible rays. Examples of the photopolymerization initiator include benzoin ethers such as benzoin methyl ether, benzoin ethyl ether, benzoin isopropyl ether, benzoin isobutyl ether, and benzoin phenyl ether; benzophenones such as benzophenone, N,N′-tetramethyl-4,4′-diaminobenzophenone (Michler's ketone) and N,N′-tetraethyl-4,4′-diaminobenzophenone; benzyl ketals such as benzyl dimethyl ketal (IRGACURE 651, manufactured by Ciba Japan K.K.), and benzyl diethyl ketal; acetophenones such as 2,2-dimethoxy-2-phenylacetophenone, p-tert-butyldichloroacetophenone, and p-dimethylaminoacetophenone; xanthones such as 2,4-dimethylthioxanthone, and 2,4-diisopropylthioxanthone; and hydroxycyclohexyl phenyl ketone (IRGACURE 184, manufactured by Ciba Specialty Chemicals, Inc.), 1-(4-isopropylphenyl)-2-hydroxy-2-methylpropane-1-one (DAROCURE 1116, manufactured by Ciba Japan K.K.), and 2-hydroxy-2-methyl-1-phenylpropane-1-one (DAROCURE 1173, manufactured by Merck & Co., Inc.). These initiators may be used singly, or in the form of a mixture of two or more thereof.

The photopolymerization initiator may be, for example, a combination of a 2,4,5-triallylimidazole dimer with 2-mercaptobenzoxazole, leuco crystal violet, or tris(4-diethylamino-2-methylphenyl)methane. A known additive, for example, tertiary amine such as triethanolamine for benzophenone may be appropriately used.

The blend amount of the photopolymerization initiator is, for example, from 0.1 to 5 parts by weight for 100 parts by weight of the matrix resin.

The refractive index of the matrix resin ranges, for example, from 1.4 to 1.7, from 1.45 to 1.65 or from 1.45 to 1.55. In some embodiments, the refractive index of the polymer matrix material is 1.5.

The wavelength-converting encapsulant composition can be produced, for example, by dispersing the above-defined fluorescent dye compound having a wavelength-converting function into the above-defined matrix resin.

The fluorescent dye compound is preferably a compound absorbing light rays having wavelengths of 340 to 410 nm more largely than light rays having wavelengths more than 410 nm. A reason therefor is as follows: in a case where the compound absorbs light rays having wavelengths more than 410 nm more largely even when the compound absorbs light rays having wavelengths of 410 nm or less, the total quantity of light rays usable in the photoelectric conversion layer is unfavorably decreased. When the compound absorbs light rays having wavelengths of 340 to 410 nm more largely than light rays having wavelengths more than 410 nm, light rays the wavelength of which has been converted also come to be usable without decreasing light rays (direct rays) usable in the photoelectric conversion layer, so that the total quantity of light rays usable in the photoelectric conversion layer can be increased.

The wavelength-converting encapsulant composition can be produced, for example, by dispersing the fluorescent dye compound having a wavelength-converting function into the matrix resin, as described above.

In the wavelength-converting encapsulant composition of the present invention, the fluorescent dye compound is contained in an amount preferably from 0.01 to 10 parts by weight, more preferably from 0.02 to 5 parts by weight, even more preferably from 0.05 to 2 parts by weight for 100 parts by weight of the resin matrix.

The wavelength-converting encapsulant composition may appropriately contain an additive as far as a desired performance thereof is not damaged. Examples of the additive include a thermoplastic polymer, an antioxidant, an ultraviolet preventing agent, a light stabilizer, an organic peroxide, a filler, a plasticizer, a silane coupling agent, an acid receiving agent, and clay. These may be used singly or in the form of a mixture of two or more thereof.

In order to produce the wavelength-converting encapsulant composition, it is sufficient to perform the production in accordance with a known method. The method is, for example, a method of heating and kneading the above-mentioned individual materials to be mixed with each other in a known manner, using, e.g., a super mixer (high-velocity flowing mixer), a roll mill, or a Plastomill. The production may be performed continuously to the production of the above-mentioned wavelength-converting encapsulant layer.

About the fluorescent dye compound, the presence of the benzotriazole structure, the content by percentage thereof and others can be guessed or checked by detecting and analyzing secondary ions even when this compound is at any one of the stage of the fluorescent dye compound, and the stages of a wavelength-converting encapsulant composition, a wavelength-converting encapsulant layer and a solar cell module each as described above. For example, about the fluorescent dye compound, the following secondary ions can be detected: a negative secondary ion at 382.2 that has a peak originating from a benzotriazole structure obtained by the cleavage of a bond between N—Y₃ in the general formula (I)

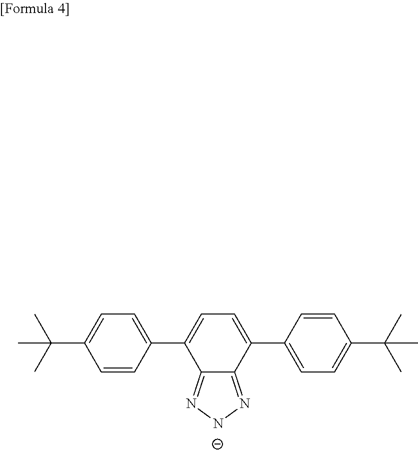

### (Wavelength-Converting Encapsulant Layer)

The wavelength-converting encapsulant layer of the present invention is a layer formed, using the above-defined wavelength-converting encapsulant composition.

The wavelength-converting encapsulant layer makes use of the wavelength-converting encapsulant composition, which contains the fluorescent dye compound having a reaction moiety (moiety fixable to a matrix) as described above. Thus, in the step of curing the wavelength-converting encapsulant composition or the wavelength-converting encapsulant layer, the fluorescent dye can be easily and simultaneously fixed thereto. This matter is very good also for industrial processes. When or after the wavelength-converting encapsulant layer is formed, or when or after the module is mounted, the fixation onto the polymer of the matrix can be generally attained by, for example, light radiating treatment, heating treatment for the fixation, light radiating treatment, or a different heating treatment. The fixation may be partially or wholly performed at the stage of the wavelength-converting encapsulant composition.

In order to produce the wavelength-converting encapsulant layer, it is sufficient to perform the production in accordance with a known method. This layer can be appropriately produced by, for example, a method of heating and kneading the above-mentioned individual materials to be mixed with each other in a known manner, using, e.g., a super mixer (high-velocity flowing mixer), a roll mill or a Plastomill, and then shaping the resultant composition into a sheet product by, e.g., an ordinary extrusion, calendering, or vacuum hot press. Moreover, this layer can be produced by forming the same layer as described just above onto, e.g., a PET film, and then transferring this layer onto a surface protective layer. Furthermore, a method is usable in which a hot melt applicator is used to knead and melt the composition simultaneously with the application of the composition.

More specifically, for example, the wavelength-converting encapsulant composition, which contains the matrix resin, the fluorescent dye compound and others, may be applied, as it is, onto, e.g., a surface protective layer or a separator, or this material may be applied in the state of being mixed with a different material to be made into a mixed composition. The wavelength-converting encapsulant composition may be formed by, e.g., vapor deposition, sputtering or an aerosol deposition method.

In the case of the application of the mixed composition, the melting point of the matrix resin is preferably from 50 to 250° C., more preferably from 50 to 200° C., even more preferably from 50 to 180° C., considering the workability of the composition. When the melting point of the wavelength-converting encapsulant composition is, for example, from 50 to 250° C., the kneading and melting temperature of the composition, and the application temperature thereof are each preferably a temperature of the melting point plus a temperature of 30 to 100° C.

In some embodiments, the wavelength-converting encapsulant layer is produced into a thin film structure through the following steps: step (i) of preparing a polymer solution in which a polymer (matrix resin) powder is dissolved in a solvent (such as tetrachloroethylene (TCE), cyclopentanone, or dioxane) to give a predetermined proportion; step (ii) of preparing a luminescent dye (such as a fluorescent dye compound) containing a polymer mixture by mixing the polymer solution with the luminescent dye at a predetermined ratio by weight therebetween to yield a dye-containing polymer solution; step (iii) of forming a dye/polymer thin film by causing the dye-containing polymer solution to flow directly onto a glass substrate, subsequently treating the substrate thermally at temperatures from room temperature to at highest 100° C. over 2 hours, and then heating the resultant in a vacuum at 130° C. all night to remove the remaining solvent; step (iv) of peeling off the dye/polymer thin film in water and then drying the resultant self-standing type polymer film completely before the thin film structure is used; and step (v) of being able to control the thickness of the film by changing the concentration in the dye/polymer solution, and the evaporation velocity thereof.

The thickness of the wavelength-converting encapsulant layer is preferably from 20 to 2000 μm, more preferably from 50 to 1000 μm, even more preferably from 100 to 800 μm. If the thickness is smaller than 5 μm, this layer does not easily express a wavelength-converting function. In the meantime, if the thickness is larger than 400 μm, this layer is lowered in adhesiveness onto a different layer to be disadvantageous for costs. The use of the wavelength-converting encapsulant layer makes it possible to prevent the dye compound from bleeding out, or decrease the bleeding-out largely even when the wavelength-converting encapsulant layer is rendered, for example, a thin layer of 600 μm thickness.

The optical thickness (absorbance) of the wavelength-converting encapsulant layer is preferably from 0.5 to 6, more preferably from 1 to 4, even more preferably from 1 to 3. If the absorbance is low, this layer does not easily express a wavelength-converting function. In the meantime, if the absorbance is too large, a disadvantage is produced for costs. The absorbance is a value calculated out in accordance with the Lambert-Beer law.

### (Solar Cell Module)

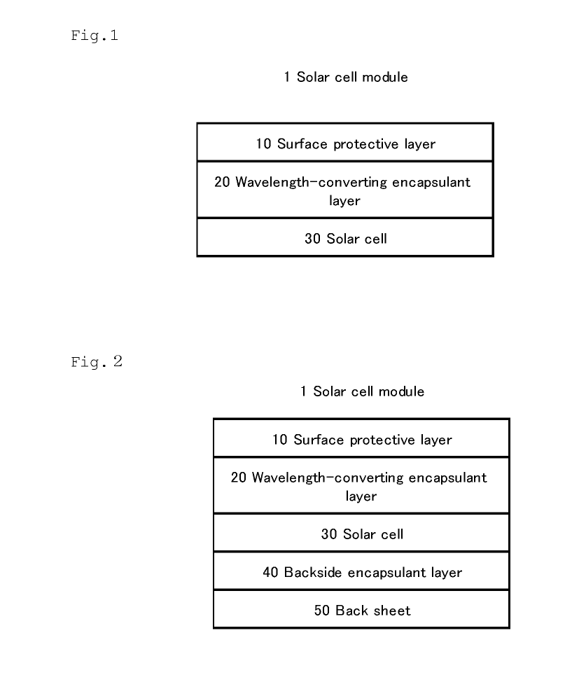

A solar cell module 1 of the present invention includes a surface protective layer 10, a layer 20 for a solar cell that is the above-defined encapsulant layer, and a solar cell 30. A simple schematic view thereof is illustrated, as an example, in each of FIGS. 1 and 2. However, the present invention is not limited to these examples. The solar cell may further have, on the rear surface side thereof, another encapsulant layer 40, and a back sheet 50. As far as the function of the encapsulant layer for a solar cell is not damaged, between any two of these layers a different layer such as an adhesive layer or a pressure-sensitive adhesive layer may fittingly be interposed. The encapsulant layer for the back surface may be a wavelength-converting encapsulant layer of the present invention as the case may be.

The solar cell module has the above-defined wavelength-converting encapsulant layer to make it possible to convert wavelengths which do not usually contribute to photoelectric conversion to wavelengths which can contribute to photoelectric conversion. Specifically, a certain wavelength can be converted to a longer wavelength. For example, wavelengths shorter than 380 nm can be converted to wavelengths of 380 nm and more. The solar cell module is a module converting, in particular, ultraviolet ray wavelengths (of 200 to 365 nm) to visible ray wavelengths (of 400 to 800 nm). This range of wavelengths contributing to photoelectric conversion is varied in accordance with the species of the solar cell. Even when this solar cell is, for example, a silicon solar cell, the range is varied in accordance with the crystal form of the used silicon. In the case of, for example, an amorphous silicon solar cell and a polycrystal silicon solar cell, the respective photoelectric-conversion-contributing wavelength ranges thereof would be from 400 to 700 nm, and from about 600 to 1100 nm. Thus, wavelengths contributing to photoelectric conversion are not necessarily limited to visible ray wavelengths. Furthermore, since the solar cell module of the present invention has the wavelength-converting encapsulant layer, the fluorescent dye compound does not precipitate even in a long-term storage test of the module, so that the fluorescent dye compound can be restrained from being shifted to the encapsulant layer 40 for the rear surface, or to some other member. Thus, the solar cell module is a stable and uniform solar cell module.

The above-mentioned solar cell may be, for example, a cadmium-sulfide/cadmium-telluride solar cell, a copper indium galliumbiselenide solar cell, an amorphous or microcrystalline silicon solar cell, or a crystal silicon solar cell. More specifically, the solar cell can be applied to a silicon solar cell, using, e.g., an amorphous silicon or polycrystal silicon, a compound semiconductor solar cell using, e.g., GaAs, CIS or CIGS, or an organic solar cell such as an organic thin film solar cell, a dye-sensitized solar cell or quantum dot solar cell. In any one of these cases, according to an ordinary use of the solar cell in the present invention, ultraviolet ray wavelengths do not easily contribute to photoelectric conversion. The solar cell is preferably a crystal silicon solar cell.

In the production of the solar cell module, the above-mentioned encapsulant layer for a solar cell may be transferred onto the solar cell or the like, or may be applied and formed directly onto the solar cell. The encapsulant layer for a solar cell and any other layer may be simultaneously formed.

The solar cell module of the present invention is preferably configured in such a manner that rays radiated into the module passes through the wavelength-converting encapsulant layer before the rays reach the solar cell. The configuration makes it possible to convert a broader spectrum of solar energy into electricity, with a higher certainty, to heighten the module in photoelectric conversion efficiency.

The above-mentioned surface protective layer may be a known layer usable as a surface protective layer for a solar cell. The surface protective layer may be, for example, a front sheet, or a glass piece. As the glass piece, various glass pieces may be fittingly used, examples thereof including a white glass plate, or a glass piece with or without embossment.

### EXAMPLES

Hereinafter, a description will be made about working examples thereof that specifically demonstrate the structure and the advantageous effects of the present invention, and others.

### Example 1

An aqueous HBr solution (32%, 350 mL) was added to 2-(6-chlorohexyl)-2H-benzotriazole (71.3 g, 300 mmol), and the resultant was heated at 110° C. Furthermore, bromine (130.0 g, 820 mmol) was bit by bit added thereto, and further the resultant was heated and stirred at 135° C. for 3 hours. After the end of the reaction, cold water and toluene were poured into this aqueous solution, and then the organic phase was taken out. Thereafter, the phase was successively washed with an aqueous saturated potassium hydroxide solution and an aqueous saturated sodium thiosulfate solution. The phase was then dried with anhydrous sodium sulfate, filtrated, and concentrated under a reduced pressure. The resultant crude composition was recrystallized from ethanol to yield 4,7-dibromo-2-(6-chlorohexyl)-2H-benzotriazole (87.0 g, 220 mL, yield: 73%).

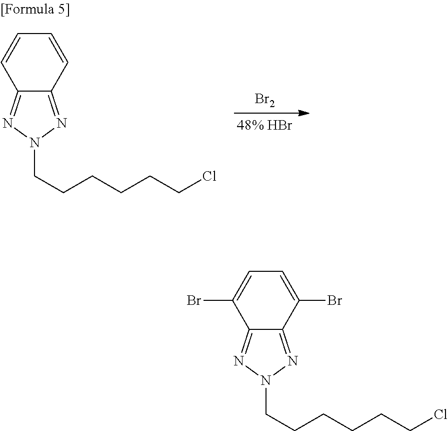 [SMILES: ClCCCCCCn1nc2ccccc2n1 ; "Br2" ; ClCCCCCCn1nc2c(Br)ccc(Br)c2n1]

Into a three-necked flask (200 mL) were charged 4,7-dibromo-2-(6-chlorohexyl)-2H-benzotriazole (3.33 g, 10 mmol), 4-tert-butylphenylboronic acid (3.92 g, 22 mmol), Pd(PPh₃)₄ (92 mg, 0.08 mmol), and potassium carbonate (4.15 g, 30 mmol). The flask was purged with nitrogen, and then thereto was added DMF (40 mL). Thereafter, thereto was added distilled water (20 mL) subjected to nitrogen bubbling treatment, and the resultant was stirred at 100° C. for 2 hours. Water (200 mL) was added to the resultant reaction solution, and then the deposited precipitation was dissolved into ethyl acetate (50 mL), and further thereto was added hexane (10 mL). A black precipitation deposited by the addition of hexane was filtrated off. The filtrate was concentrated under a reduced pressure. The resultant residue was heated and dissolved into isopropanol (100 mL), and then cooled (recrystallized) to yield 4,7-bis-(4-tert-butylphenyl)-2-(6-chlorohexyl)-2H-benzotriazole (4.61 g, 7.9 mmol, yield: 79%).

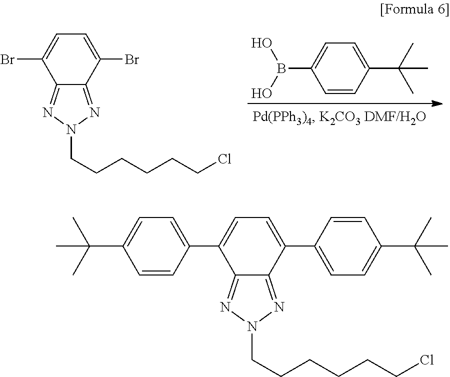

Into a three-necked flask (100 mL) were charged 4,7-bis-(4-tert-butylphenyl)-2-(6-chlorohexyl)-2H-benzotriazole (2.80 g, 5.57 mmol), potassium carbonate (2.31 g, 16.7 mmol), BHT (1.0 g), and methacrylic acid (0.96 g, 11.2 mmol). The flask was purged with nitrogen, and then thereto was added DMF (20 mL). Thereafter, the resultant was stirred at 120° C. for 6 hours. Water (200 mL) was added to the resultant reaction solution, and then the deposited precipitation was filtrated off. The resultant precipitation was dissolved into ethyl acetate (50 mL), and the solution was washed with distilled water. The organic phase was then concentrated under a reduced pressure. The resultant residue was heated and dissolved into isopropanol (100 mL), and then cooled (recrystallized) to yield 4,7-bis-(4-tert-butylphenyl)-2-(6-methacrylhexyl)-2H-benzotriazole (compound (1), 2.18 g, 3.95 mmol, yield: 71%).

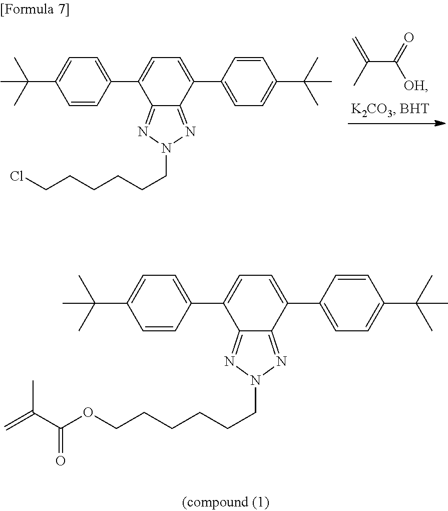

### Example 2

Acrylic acid was used instead of methacrylic acid in Example 1 to yield 4,7-bis-(4-tert-butylphenyl)-2-(6-acrylhexyl)-2H-benzotriazole (compound (2), 2.04 g, 3.80 mmol, yield: 68%).

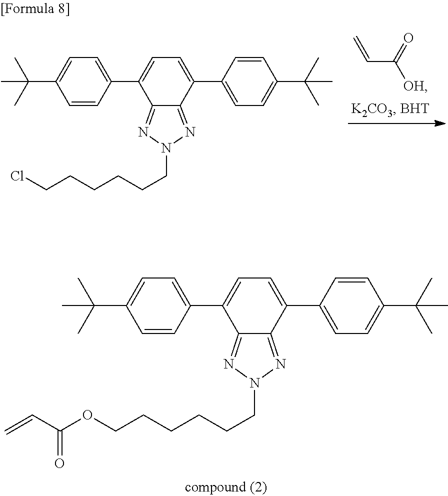

### Example 3

In a three-necked flask (100 mL) were prepared 4,7-bis-(4-tert-butylphenyl)-2-(6-chlorohexyl)-2H-benzotriazole (2.80 g, 5.57 mmol), potassium-t-butoxide (6.25 g, 55.7 mmol), and BHT (1.0 g). The flask was purged with nitrogen, and then thereto was added THF (30 mL) while the liquid in the flask in an ice bath was stirred. The liquid was stirred at room temperature for 2 hours. The flask was cooled with the air, and then diluted hydrochloric acid was added thereto to neutralize the liquid. The resultant system was extracted with water/ethyl acetate. The system was washed with distilled water, and then the organic layer was concentrated under a reduced pressure. The resultant residue was heated and dissolved into isopropanol (100 mL), and then cooled (recrystallized) to yield 4,7-bis-(4-tert-butylphenyl)-2-(6-hexenyl)-2H-benzotriazole (compound (3), 1.85 g, 3.98 mmol, yield: 71%).

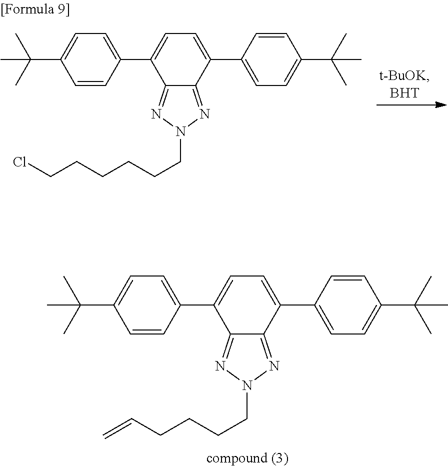

### Example 4

Into a three-necked flask (200 mL) were charged 4,7-dibromo-2-octyl-2H-benzotriazole (3.89 g, 10 mmol), 2-hydroxyphenylboronic acid (3.03 g, 22 mmol), Pd(PPh₃)₄ (92 mg, 0.08 mmol), and potassium carbonate (4.15 g, 30 mmol). The flask was purged with nitrogen, and then thereto was added DMF (40 mL). Thereafter, thereto was added distilled water (20 mL) subjected to nitrogen bubbling treatment, and the resultant was stirred at 100° C. for 2 hours. Allyl glycidyl ether (11.41 g, 100 mmol) was added to the resultant reaction solution, and further the resultant was stirred at 80° C. for 3 hours. The resultant reaction solution was extracted with ethyl acetate. The extracted liquid was washed with water, and the organic solvent in the resultant organic phase was distilled off under a reduced pressure. The resultant residue was purified by column chromatographic treatment (eluent: toluene/ethyl acetate=16/1) to yield 4,7-bis-(2-(3-allyloxy-2-hydroxypropioxy)phenyl)-2-octyl-2H-benzotriazole (compound (4), 7.64 g, 8.10 mmol, yield: 83%)

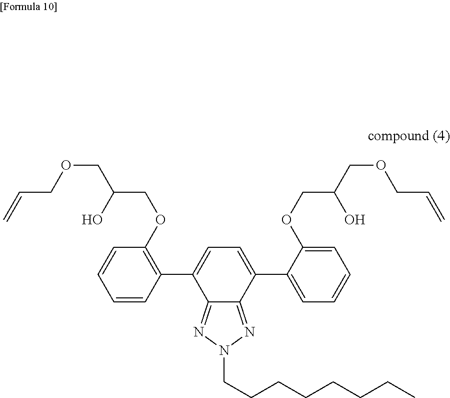 [SMILES: C=CCOCC(O)COc1ccccc1-c1ccc(-c2ccccc2OCC(O)COCC=C)c2nn(CCCCCCCC)nc12]

### Example 5

Into a three-necked flask (200 mL) were charged 4,7-dibromo-2-octyl-2H-benzotriazole (3.89 g, 10 mmol), 4-hydroxyphenylboronic acid (3.03 g, 22 mmol), Pd(PPh₃)₄ (92 mg, 0.08 mmol), and potassium carbonate (4.15 g, 30 mmol). The flask was purged with nitrogen, and then thereto was added DMF (40 mL). Thereafter, thereto was added distilled water (20 mL) subjected to nitrogen bubbling treatment, and the resultant was stirred at 100° C. for 2 hours. Water (200 mL) was added to the resultant reaction solution, and the deposited precipitation was filtrated off. The resultant precipitation was dissolved into acetone and isopropanol, and the insoluble matter was hot-filtrated to be collected. The resultant residue was heated and dissolved in isopropanol (100 mL), and then cooled (recrystallized) to yield 4,7-bis-(4-hydroxyphenyl)-2-octyl-2H-benzotriazole (3.49 g, 8.40 mmol, yield: 84%).

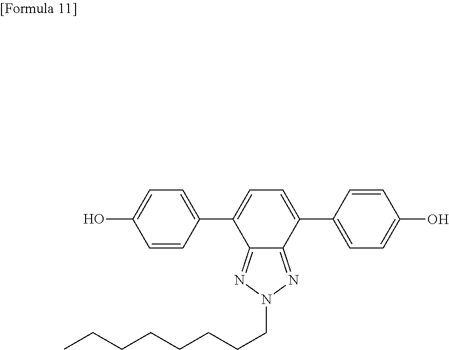 [SMILES: CCCCCCCCn1nc2c(-c3ccc(O)cc3)ccc(-c3ccc(O)cc3)c2n1]

Into a three-necked flask (100 mL) were charged 4,7-bis(4-hydroxyphenyl)-2-octyl-2H-benzotriazole (0.39 g, 0.936 mmol), potassium carbonate (0.65 g, 4.689 mmol), and allyl bromide (0.56 g, 4.689 mmol). The flask was purged with nitrogen, and then thereto was added DMF (10 mL). Thereafter, the resultant was stirred at 100° C. for 3 hours. Water (200 mL) was added to the resultant reaction solution, and the deposited precipitation was filtrated off. The resultant precipitation was dissolved into ethyl acetate (50 mL), and further hexane (10 mL) was added thereto. A black precipitation deposited by the addition of hexane was filtrated off, and the filtrate was concentrated under a reduced pressure. The resultant residue was heated and dissolved into isopropanol, and then cooled (recrystallized) to yield 4,7-bis-(4-allyloxy)-2-octyl-2H-benzotriazole (compound (5), 0.29 g, 0.66 mmol, yield: 71%).

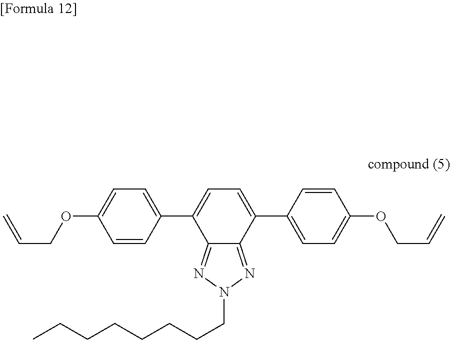 [SMILES: C=CCOc1ccc(-c2ccc(-c3ccc(OCC=C)cc3)c3nn(CCCCCCCC)nc23)cc1]

### Example 6

Into a three-necked flask (100 mL) were charged 4,7-bis(4-hydroxyphenyl)-2-octyl-2H-benzotriazole (0.39 g, 0.936 mmol), oleic acid (0.794 g, 2.81 mmol), and dimethylaminopyridine (catalytic amount). The flask was purged with nitrogen, and then these components were suspended into methylene chloride (10 ml), and further thereto was added 3-dimethylaminopropylethylcarbodiimide hydrochloride (0.39 g, 2.81 mmol). Thereafter, the resultant was stirred at room temperature for 40 hours. The resultant reaction solution was extracted with ethyl acetate, and the extracted liquid was washed with water. The solvent in the resultant organic phase was distilled off under a reduced pressure. The resultant residue was purified by column chromatographic treatment (eluent: toluene) to yield 4,7-bis(4-oleyloxyphenyl)-2-octyl-2H-benzotriazole (compound (6), 0.459 g, 0.487 mmol, yield: 52%).

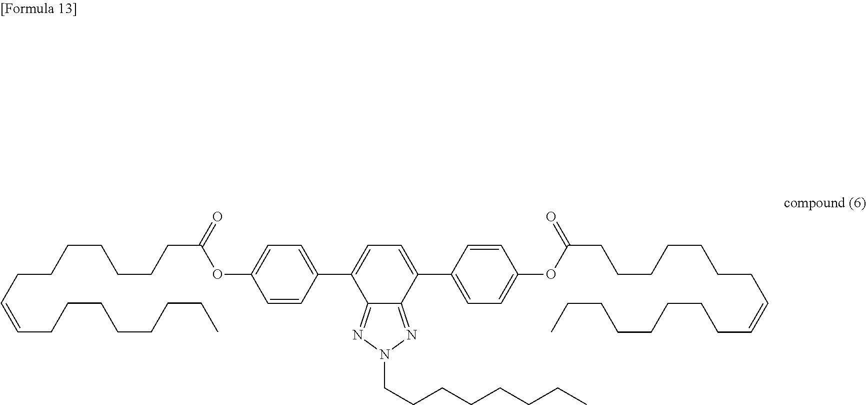 [SMILES: CCCCCCCC/C=C\CCCCCCCC(=O)Oc1ccc(-c2ccc(-c3ccc(OC(=O)CCCCCCC/C=C\CCCCCCCC)cc3)c3nn(CCCCCCCC)nc23)cc1]

### Example 7

A compound illustrated below (compound (7), 0.487 g, 0.523 mmol, yield: 58%) was yielded in the same way as in Example 5 except that instead of oleic acid in Example 6, linolenic acid was used.

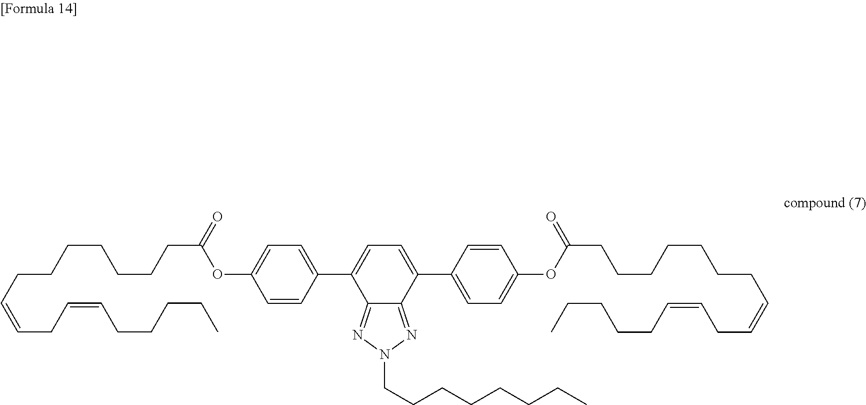 [SMILES: CCCCC/C=C\C/C=C\CCCCCCCC(=O)Oc1ccc(-c2ccc(-c3ccc(OC(=O)CCCCCCC/C=C\C/C=C\CCCCC)cc3)c3nn(CCCCCCCC)nc23)cc1]

### Example 8

A compound illustrated below (compound (8), 0.5 g, 0.601 mmol, yield: 60%) was yielded in the same way as in Example 5 except that instead of 4-hydroxyphenylboronic acid in Example 6, 3-hydroxymethylphenylboronic acid was used.

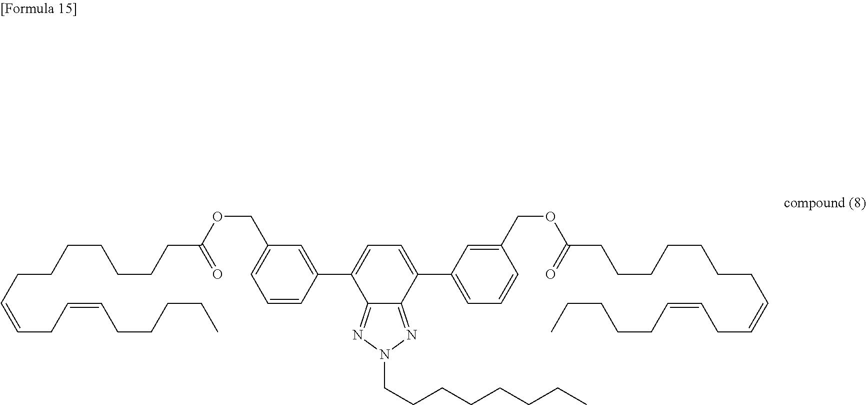 [SMILES: CCCCC/C=C\C/C=C\CCCCCCCC(=O)OCc1cccc(-c2ccc(-c3cccc(COC(=O)CCCCCCC/C=C\C/C=C\CCCCC)c3)c3nn(CCCCCCCC)nc23)c1]

### Example 9

A compound illustrated below (compound (9), 0.6 g, 0.632 mmol, yield: 63%) was yielded in the same way as in Example 4 except that instead of 4-hydroxyphenylboronic acid in Example 4, 2-hydroxymethylphenylboronic acid was used.

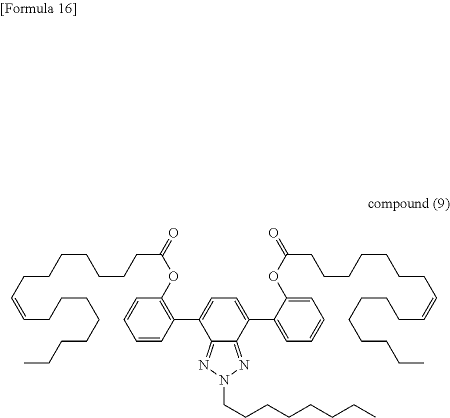 [SMILES: CCCCCCCC/C=C\CCCCCCCC(=O)Oc1ccccc1-c1ccc(-c2ccccc2OC(=O)CCCCCCC/C=C\CCCCCCCC)c2nn(CCCCCCCC)nc12]

### Comparative Example 1

Into a three-necked flask (200 mL) were charged octyl-2H-benzotriazole (3.33 g, 10 mmol), 4-tert-butylphenylboronic acid (3.92 g, 22 mmol), Pd(PPh₃)4 (92 mg, 0.08 mmol), and potassium carbonate (4.15 g, 30 mmol). The flask was purged with nitrogen, and then thereto was added DMF (40 mL). Thereafter, thereto was added distilled water (20 mL) subjected to nitrogen bubbling treatment, and the resultant was stirred at 100° C. for 2 hours. Water (200 mL) was added to the resultant reaction solution, and then the deposited precipitation was filtrated off. The resultant precipitation was dissolved into ethyl acetate (50 mL), and thereto was further added hexane (10 mL). A black precipitation deposited by the addition of hexane was filtrated off. The filtrate was concentrated under a reduced pressure. The resultant residue was heated and dissolved into isopropanol (100 mL), and then cooled (recrystallized) to yield 4,7-bis-(4-tert-butylphenyl)-2-octyl-2H-benzotriazole (4.61 g, 7.9 mmol, yield: 79%).

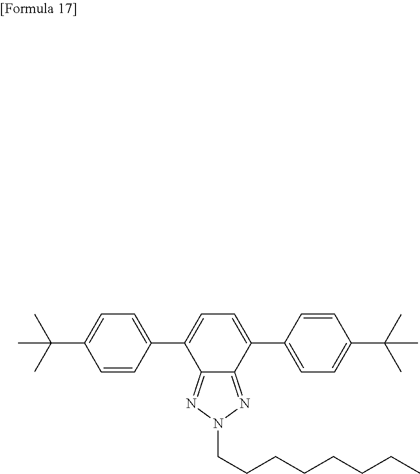 [SMILES: CCCCCCCCn1nc2c(-c3ccc(C(C)(C)C)cc3)ccc(-c3ccc(C(C)(C)C)cc3)c2n1]

### Comparative Example 2

Instead of the fluorescent dye compound in each of the working examples, 2-hydroxy-4-(octyl)benzophenone, which is a generally-used ultraviolet absorbent, was used.

### (Measurement of Maximum Absorption Wavelength, and Fluorescence Emission Wavelength)

Measurements were made about the maximum absorption wavelength and the fluorescence emission wavelength of the fluorescent dye compound used in each of the working examples and the comparative examples. The measurement of the maximum absorption wavelength was made, using an ultraviolet and visible spectrophotometer (V-560, manufactured by JASCO Corp.) The wavelength at which the maximum value was shown in the Abs measurement of the compound was measured.

The measurement of the fluorescence emission wavelength was made, using an instrument F-4500 manufactured by Hitachi High-Technologies Corp. The wavelength at which the maximum emission intensity was shown in the (excitation-emission) three-dimension measurement of the compound was measured.

### (Production of Each Encapsulant Resin Composition)

The following were weighed out: 100 parts by mass of ethylene vinyl acetate (EVA) (KA-30 manufactured by Sumitomo Chemical Co., Ltd.) as a transparent dispersion-medium resin; 0.3 part by weight of PERBUTYL E (manufactured by NOF Corp., one-hour half-time temperature: 119° C.); 1.0 part by weight of a substance TAIC (manufactured by Nippon Kasei Chemical Co., Ltd.); and 0.2 part by mass of the compound of each of the working examples and the comparative examples. A Labo Plastomill (10C100, manufactured by Toyo Seiki Kogyo Co., Ltd.) was used to knead these components at 80° C. to yield a encapsulant resin composition.

### (Production of Each Encapsulant Sheet)

Each of the encapsulant resin compositions yielded as described above was sandwiched between release sheets. A vacuum hot-press machine (VS20-3430, manufactured by Mikado Technos Co., Ltd.) was used to press the workpiece at 150° C., and then cure the workpiece at 150° C. for 20 minutes to produce a encapsulant sheet of about 500 μm thickness. In this step, the dye was fixed.

### (Time-of-Flight Secondary Ion Mass Spectrometry of Each of Encapsulant Sheets)

Respective samples of the encapsulant compositions were each fixed to a dedicated holder. The sample was then observed, using a time-of-flight secondary ion mass spectrometry [TOF-SIMS] (TRIFTV, manufactured by ULVAC-PHI, Inc.). Bi²⁺ions were radiated onto the sample piece at an accelerating voltage of 30 kV. As a result, in the case of using the wavelength conversing encapsulant of Example 1, the observation of a secondary ion illustrated below succeeded, in which Mn=382.2.

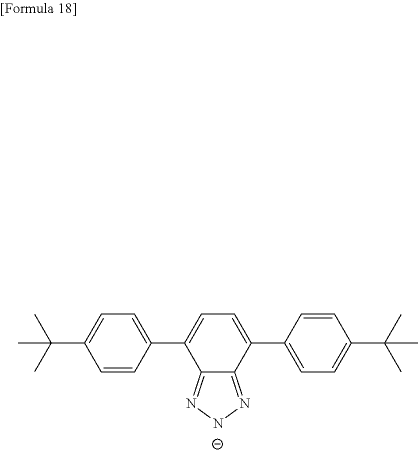 [SMILES: CC(C)(C)c1ccc(-c2ccc(-c3ccc(C(C)(C)C)cc3)c3n[n-]nc23)cc1]

### (Measurement of Efficiency of Each Solar Cell Module)

Each of the sheets obtained as described above was cut into a size of 20×20 cm. The following were then put onto each other: a reinforced glass piece (SOLITE, manufactured by Asahi Glass Co., Ltd.) as a protective glass piece; the encapsulant sheet; a solar cell (of a crystal silicon type, Q6LTT3-G2-200/1700-A, manufactured by Hanwha Q CELLS Co., Ltd.); a encapsulant sheet (400-μm-thick EVA sheet) for a rear surface; and a PET film as a back sheet. A vacuum laminator (LM-50×50-S, manufactured by NPC Inc.) was used to laminate these members onto each other at 150° C. in a vacuum state for 5 minutes and a pressured state for 20 minutes to produce a solar cell module.

### (Measurement of Jsc of Each of Solar Cell Modules)

A spectral sensitivity measuring instrument (CEP-25RR, manufactured by JASCO Corp.) was used to measure the spectral sensitivity of each of the solar cell modules yielded as described above. The Jsc value thereof was obtained which was calculated out from the spectral sensitivity measurement. The Jsc value of any sample is the short circuit current density thereof that is calculated out by an arithmetic operation of the following two: a spectral sensitivity spectrum obtained by measuring the sample through a spectral sensitivity measuring instrument; and sunlight as a reference.

According to the measurement of the Jsc value of the solar cell module produced using the encapsulant sheet of each of Example 1 and Comparative Example 2, the Jsc value of the solar cell module of Example 1 was larger than that of the solar cell module of Comparative Example 2 by 1.5%. Thus, the module of Example 1 was improved in photoelectric conversion efficiency.

### (Verification of Fixation Degree of Each of Dye Compounds)

An EVA encapsulant sheet was produced, using the fluorescent dye compound or ultraviolet absorbent synthesized in each of the working examples and the comparative examples. In such a sheet produced, its wavelength-converting dye is ideally taken into its polymer matrix; thus, even when the sheet is immersed in a solvent, the dye is not eluted out. The produced EVA encapsulant sheet was immersed in a solvent, and then the quantity of an eluted-out fragment of the dye was measured, using a spectrophotometer. A comparison was then made between these examples.

### (Production of Each Encapsulant Resin Composition)

The following were weighed out: 100 parts by mass of ethylene vinyl acetate (EVA) (KA-30 manufactured by Sumitomo Chemical Co., Ltd.) as a transparent dispersion-medium resin; 0.3 part by mass of PERBUTYL E (manufactured by NOF Corp., one-hour half-time temperature: 119° C.); 1.0 part by mass of a substance TAIC (manufactured by Nippon Kasei Chemical Co., Ltd.); and 0.2 part by mass of the compound of each of Examples 1 to 7 and Comparative Examples 1 and 2. A Labo Plastomill (10C100, manufactured by Toyo Seiki Kogyo Co., Ltd.) was used to knead these components at 80° C. to yield a encapsulant resin composition.

(Step of Producing Each Encapsulant Sheet, and Fixing Wavelength-Converting Material into Polymer Matrix)

Each of the encapsulant resin compositions yielded as described above was sandwiched between release sheets. A vacuum hot-press machine (VS20-3430, manufactured by Mikado Technos Co., Ltd.) was used to press the workpiece at 150° C., and then cure the workpiece at 150° C. for 20 minutes to produce a encapsulant sheet of about 500 μm thickness, and fix the dye thereto.

Each of the resultant encapsulant sheets, the weight of the sheet being 300 mg, was allowed to stand still in 50 mL of isopropyl alcohol at 40° C. for 4 hours, and then an evaluation was made as to whether or not the dye was eluted out. Thereafter, the resultant encapsulant sheet was dried, and then the absorbance of the encapsulant sheet was measured at the maximum absorption wavelength of this sheet. About each of the sheets, a comparison was made between the respective absorbances, at the maximum absorption wavelength, before and after the elution experiment to calculate and evaluate the proportion of the dye fixed to the resin. As the fixation degree of the dye, a value calculated out in accordance with the following equation was used:

Fixation degree(%)={(absorbance after the elution test)/(absorbance before the elution test)}×100

The resultant results are shown in Table 1 described below.

TABLE 1

| | Maximum | | Maximum | Maximum | |
|---|---|---|---|---|---|
| | emission | Maximum | absorption | absorption | |
| | absorption | emission | wavelength | wavelength | Fixation |
| | wavelength | wavelength | (before curing) | (after curing) | degree (%) |
| Example 1 | 345 nm | 425 nm | 345 nm | 425 nm | 100 |
| Example 2 | 345 nm | 425 nm | 345 nm | 425 nm | 98 |
| Example 3 | 345 nm | 425 nm | 345 nm | 425 nm | 95 |
| Example 4 | 325 nm | 400 nm | 325 nm | 400 nm | 62 |
| Example 5 | 355 nm | 430 nm | 355 nm | 430 nm | 60 |
| Example 6 | 330 nm | 410 nm | 330 nm | 410 nm | 65 |
| Example 7 | 330 nm | 410 nm | 330 nm | 410 nm | 57 |
| Example 8 | 330 nm | 410 nm | 330 nm | 410 nm | 57 |
| Example 9 | 325 nm | 415 nm | 325 nm | 415 nm | 58 |
| Comparative | 345 nm | 425 nm | 345 nm | 425 nm | 8.6 |
| Example 1 | | | | | |
| Comparative | 330 nm | — | 353 nm | — | 5.8 |
| Example 2 | | | | | |

It has been understood that in the encapsulant sheet using the compound in each of the working examples of the present application, its dye compound was fixed to its polymer film. It has been understood that the compounds of the present application were excellent in the property of not being precipitated while their chromophore maintained absorbing/light-emitting properties.

### DESCRIPTION OF REFERENCE SIGNS

1: Solar cell module
10: Surface protective layer
20: Wavelength-converting encapsulant layer
30: Solar cell
40: Backside encapsulant layer
50: Back sheet

1. A light wavelength-converting organic compound, which is fixable to a polymer matrix through a chemical bond.

2. The light wavelength-converting organic compound according to claim 1, which is fixable thereto by a crosslinking reaction, cyclization reaction, substitution reaction, or polymerization reaction.

3. The light wavelength-converting organic compound according to claim 1, which is a benzotriazole derivative.

4. The light wavelength-converting organic compound according to claim 1, wherein the polymer matrix comprises, as a main component thereof, an ethylene-vinyl acetate copolymer.

5. A fluorescent dye compound, represented by the following general formula (I): 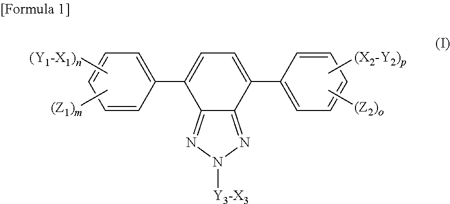
wherein X₁(s) and X₂(s) each independently represent —O—, —(C═O)O—, —O(C═O)—, —CH₂O—, —CH₂O(CO)—, —NH(CO)—, —NR—CH₂—, or a single bond wherein R represents an alkyl group having 1 to 8 carbon atoms;
X₃ represents a group containing a carbon-carbon double bond, or hydrogen;
Y₁(s) and Y₂(s) each independently represent an optionally-substituted alkyl group having 1 to 18 carbon atoms, or an optionally-substituted alkyl group having a carbon-carbon double bond and having 2 to 18 carbon atoms (provided that one or two out of any nonadjacent two of the carbon atoms in the alkyl group may (each) be substituted with an oxygen atom);
Y₃ represents an optionally-substituted alkyl group having 1 to 18 carbon atoms, an optionally-substituted aryl group having 5 to 18 carbon atoms, or an optionally-substituted alkyl group having a carbon-carbon double bond and having 2 to 18 carbon atoms (provided that one or two out of any nonadjacent two of the carbon atoms in the alkyl group may (each) be substituted with an oxygen atom);
one or more of the symbols Y₁(s), Y₂(s), Y₃ and X₃ (each) have a carbon-carbon double bond;
Z₁(s) and Z₂(s) each independently represent an optionally-substituted alkyl group having 1 to 18 carbon atoms (provided that one or two out of any nonadjacent two of the carbon atoms in the alkyl group may (each) be substituted with an oxygen atom), an optionally-substituted alkoxy group having 1 to 18 carbon atoms (provided that one or two out of any nonadjacent two of the carbon atoms in the alkoxy group may (each) be substituted with an oxygen atom), a fluoro group, a cyano group, —COOR¹ group, —NHCOR² group, or a hydroxyl group wherein R¹ and R² each represent an alkyl group having 1 to 18 carbon atoms or a phenyl group; and
m, n, o and p each independently represent an integer of 0 to 4 (provided that m+n is 4 or less, and o+p is 4 or less), and when m, n, o or p is 2 or more, the substituents concerned may be the same as or different from each other.

6. The fluorescent dye compound according to claim 5, wherein the symbol X₃ is —CR′═CH₂, —(C═O)O—CR′═CH₂, —O(C═O)—CR′═CH₂, —CH₂O(CO)—CR′═CH₂, —NH(CO)—CR′═CH₂, or —NR—CH₂—CR′═CH₂ wherein R and R's each independently represent an alkyl group having 1 to 8 carbon atoms.

7. The fluorescent dye compound according to claim 5, which has a maximum absorption wavelength in a range from 340 to 410 nm.

8. The fluorescent dye compound according to claim 5, which has a maximum fluorescence emission wavelength in a range from 440 to 560 nm.

9. A wavelength-converting encapsulant composition, comprising an optically transparent resin matrix, and the fluorescent dye compound according to claim 5.

10. A wavelength-converting encapsulant composition, comprising the fluorescent dye compound recited in any one of claim 9 in an amount of 0.01 to 10 parts by weight for 100 parts by weight of the resin matrix.

11. The wavelength-converting encapsulant composition according to claim 9, wherein the matrix resin comprises, as a main component thereof, poly(ethylene-vinyl acetate).

12. A wavelength converting encapsulant layer, which is formed using the wavelength-converting encapsulant composition according to claim 9.

13. A solar cell module, comprising a wavelength-converting encapsulant layer formed using the wavelength-converting encapsulant composition according to claim 9.

14. The solar cell according to claim 13, which is configured to cause a light ray radiated into the module to pass through the wavelength-converting encapsulant layer before the light ray reaches a solar cell of the module.

15. The solar cell module according to claim 13, wherein the solar cell is a crystal silicon solar cell.
